(19) United States
(12) Patent Application Publication
(10) Pub. No.: US 2024/0321874 A1
(43) Pub. Date: Sep. 26, 2024

(54) INTEGRATED CIRCUIT DEVICE

(71) Applicant: SAMSUNG ELECTRONICS CO., LTD., Suwon-si (KR)

(72) Inventors: Jeonghyeon Lee, Suwon-si (KR); Hakjong Lee, Suwon-si (KR); Yeonghan Gwon, Suwon-si (KR); Hanyoung Song, Suwon-si (KR); Subin Lee, Suwon-si (KR); Junyoup Lee, Suwon-si (KR); Hyunjun Lim, Suwon-si (KR); Taeho Cha, Suwon-si (KR); Seunghyeon Hong, Suwon-si (KR)

(21) Appl. No.: 18/499,117

(22) Filed: Oct. 31, 2023

(30) Foreign Application Priority Data
Mar. 24, 2023 (KR) 10-2023-0039186
Apr. 26, 2023 (KR) 10-2023-0054975

(51) Int. Cl. H01L 27/088; H01L 21/762; H01L 21/8234

(52) U.S. Cl. CPC H01L 27/088; H01L 21/76224; H01L 21/823481

(57) ABSTRACT

An integrated circuit device includes a pair of fin-type active regions collinear with each other on a substrate, a gate line disposed on one of the fin-type active regions, a capping insulating layer that covers the gate line, and a fin isolation insulating portion that passes through the capping insulating layer in a vertical direction between the pair of fin-type active regions. The fin isolation insulating portion includes an isolation insulating plug that includes a first portion disposed between the pair of fin-type active regions and a second portion integrally connected to the first portion and that passes through the capping insulating layer in the vertical direction, and an isolation insulating liner that surrounds a bottom surface and a sidewall of the isolation insulating plug. The isolation insulating liner includes an uppermost portion that is closer to the substrate than a top surface of the isolation insulating plug.

### CROSS-REFERENCE TO RELATED APPLICATION

This application claims priority under 35 U.S.C. § 119 from Korean Patent Applications Nos. 10-2023-0039186 and 10-2023-0054975, respectively filed on Mar. 24, 2023 and Apr. 26, 2023 in the Korean Intellectual Property Office, the contents of both of which are herein incorporated by reference in their entireties.

### TECHNICAL FIELD

Embodiments of the inventive concept are directed to a method of manufacturing an integrated circuit (IC) device, and more particularly, to an IC device that includes a fin-type active region.

### DISCUSSION OF THE RELATED ART

As IC devices have become downscaled, the IC devices need to ensure not only a high operating speed but also high operating accuracy and high reliability.

### SUMMARY

Embodiments of the inventive concept provide an integrated circuit (IC) device that includes a device region that has a reduced area with a downscaled trend and a structure that improves reliability even when aspect ratios of components included in the device region increase.

According to an embodiment of the inventive concept, there is provided an integrated circuit device that includes a pair of fin-type active regions that extend in a first lateral direction on a substrate, where the pair of fin-type active regions are collinear with each other in the first lateral direction, a gate line that extends in a second lateral direction on one of the fin-type active regions, where the second lateral direction crosses the first lateral direction, a capping insulating layer that covers a top surface of the gate line, and a fin isolation insulating portion that extends in the second lateral direction between the pair of fin-type active regions, where the fin isolation insulating portion passes through the capping insulating layer in a vertical direction that is perpendicular to a plane defined by the first lateral direction and the second lateral direction. The fin isolation insulating portion includes an isolation insulating plug that includes a first portion and a second portion, where the first portion is interposed between the pair of fin-type active regions, and the second portion is integrally connected to the first portion and passes through the capping insulating layer in the vertical direction, and an isolation insulating liner that surrounds a bottom surface and a sidewall of the isolation insulating plug. The isolation insulating liner includes an uppermost portion that is closer to the substrate than a top surface of the isolation insulating plug.

According to another embodiment of the inventive concept, there is provided an integrated circuit device that includes a pair of fin-type active regions that extend in a first lateral direction on a substrate, where the pair of fin-type active regions are collinear with each other in the first lateral direction, a fin isolation insulating portion that extends in a second lateral direction between the pair of fin-type active regions, where the second lateral direction crosses the first lateral direction, a pair of nanosheet stacks respectively disposed on the pair of fin-type active regions, where each nanosheet stack includes at least one nanosheet, a pair of gate lines that surround the at least one nanosheet on the pair of fin-type active regions, where the pair of gate lines extend in the second lateral direction, a capping insulating layer that covers top surfaces of the pair of gate lines, and a pair of source/drain regions respectively disposed on both sides of the fin isolation insulating portion between the pair of gate lines. The fin isolation insulating portion includes an isolation insulating plug that includes a first portion and a second portion, where the first portion is disposed between the pair of fin-type active regions and the second portion is integrally connected to the first portion and passes through the capping insulating layer in a vertical direction that is perpendicular to a plane defined by the first lateral direction and the second lateral direction, and an isolation insulating liner that surrounds a bottom surface and a sidewall of the isolation insulating plug. The isolation insulating liner includes an uppermost portion that is closer to the substrate than a top surface of the isolation insulating plug.

According to another embodiment of the inventive concept, there is provided an integrated circuit device that includes a pair of fin-type active regions that extend in a first lateral direction on a substrate, where the pair of fin-type active regions are collinear with each other in the first lateral direction, a fin isolation insulating portion that extends in a second lateral direction between the pair of fin-type active regions, where the second lateral direction crosses the first lateral direction, a pair of nanosheet stacks respectively disposed on the pair of fin-type active regions, where each nanosheet stack includes at least one nanosheet, a first pair of gate lines that surround the at least one nanosheet on the pair of fin-type active regions, where the first pair of gate lines extend in the second lateral direction, a second pair of gate lines that are spaced apart from the first pair of gate lines in the second lateral direction, where the second pair of gate lines extend along extension lines of the first pair of gate lines in the second lateral direction, a capping insulating layer that covers respective top surfaces of the first pair of gate lines and the second pair of gate lines, and a gate cut insulating portion disposed between the first pair of gate lines and the second pair of gate lines, where the gate cut insulating portion extends in the first lateral direction and is integrally connected to the fin isolation insulating portion. Each of the fin isolation insulating portion and the gate cut insulating portion includes an insulating plug that passes through the capping insulating layer in a vertical direction is perpendicular to a plane defined by the first lateral direction and the second lateral direction, where the insulating plug includes a top surface and a sidewall in contact with the capping insulating layer, and the top surface is coplanar with a top surface of the capping insulating layer, and an insulating liner that surrounds a bottom surface and a sidewall of the insulating plug, where the insulating liner includes an uppermost portion that is closer to the substrate than a top surface of the insulating plug.

### BRIEF DESCRIPTION OF THE DRAWINGS

FIG. 1 is a plan layout diagram of an integrated circuit (IC) device according to embodiments.

FIG. 2A is a cross-sectional view taken along line X1-X1′ of FIG. 1.

FIG. 2B is a cross-sectional view taken along line Y1-Y1′ of FIG. 1.

FIG. 2C is an enlarged cross-sectional view of local area “EX2” of FIG. 2A.

FIG. 2D is an enlarged cross-sectional view of local area “EX3” of FIG. 2B.

FIG. 3A is a plan layout diagram of an IC device according to embodiments.

FIG. 3B is a cross-sectional view taken along line X2-X2′ of FIG. 3A.

FIG. 4 is a cross-sectional view of an IC device according to embodiments.

FIG. 5 is a cross-sectional view of an IC device according to embodiments.

FIGS. 6A to 22B are cross-sectional views that illustrate a method of manufacturing an IC device, according to embodiments, in which FIGS. 6A, 9A, 10A, 11A, 12A, 13A, 14A, 15A, 16A, 17A, 18A, 19A, 20A, 21A, and 22A are cross-sectional views taken along line X1-X1′ of FIG. 1, and FIGS. 6B, 7, 8, 9B, 10B, 11B, 12B, 13B, 14B, 15B, 16B, 17B, 18B, 19B, 20B, 21B, and 22B are cross-sectional views taken along line Y1-Y1′ of FIG. 1.

### DETAILED DESCRIPTION

Hereinafter, embodiments will be described in detail with reference to the accompanying drawings. The same reference numerals may be used to denote the same elements in the drawings, and repeated descriptions thereof may be omitted. When one component is described as being in contact with a second component, the one component is in direct contact with the second component, without any intervening layer in between.

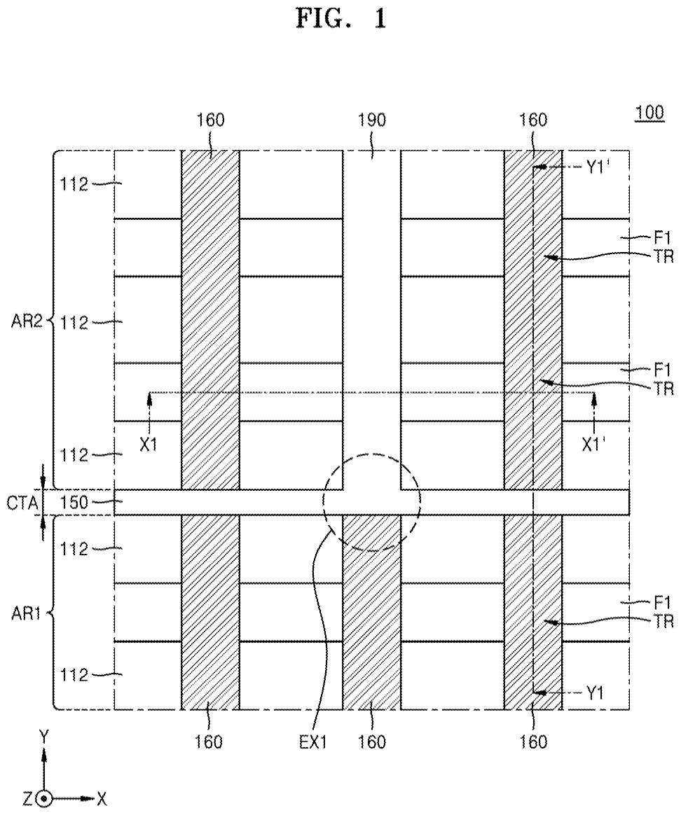

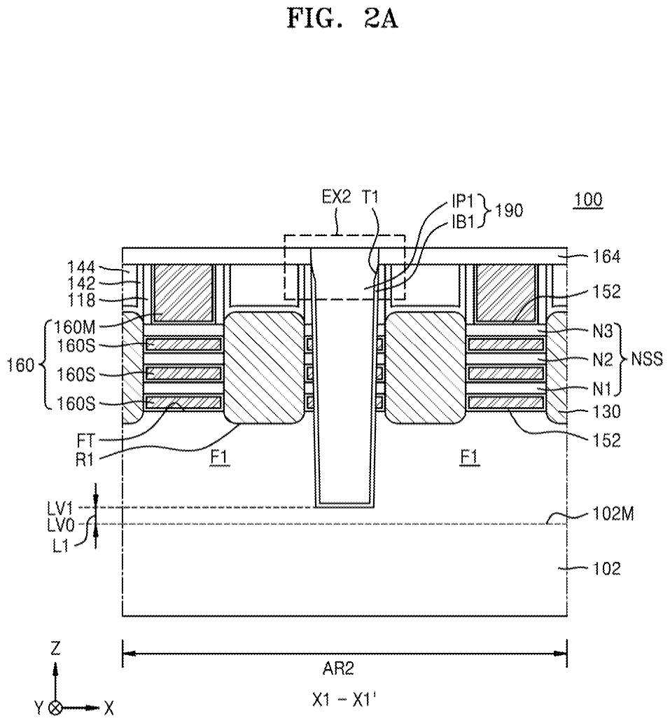

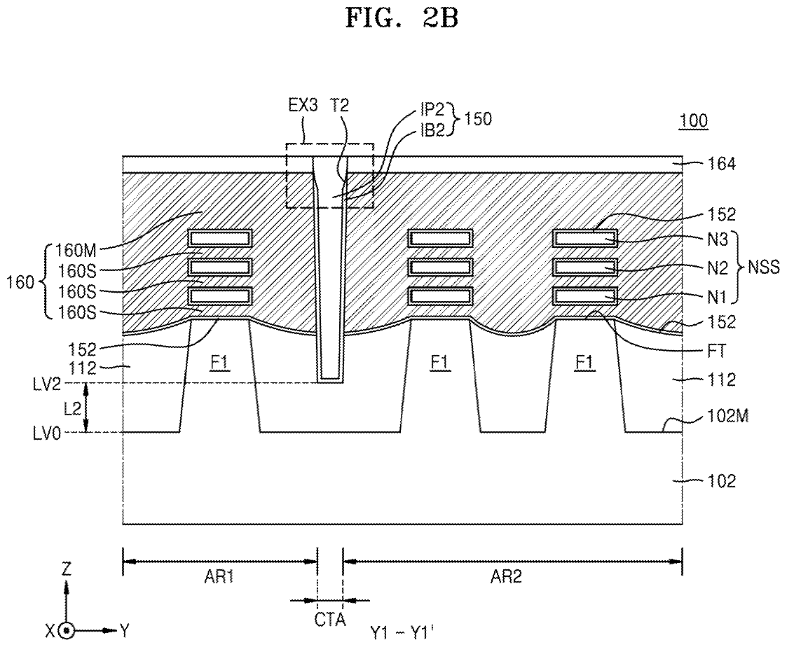

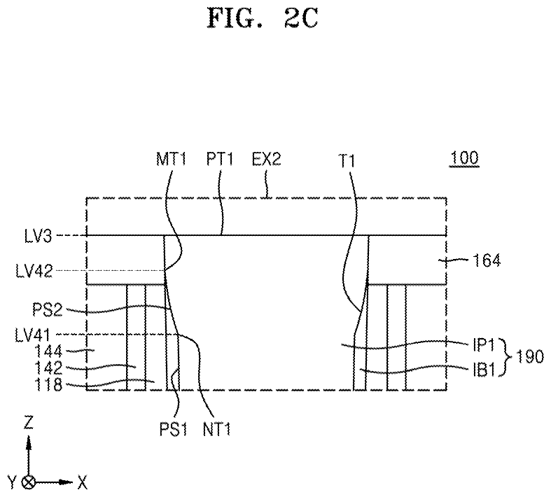

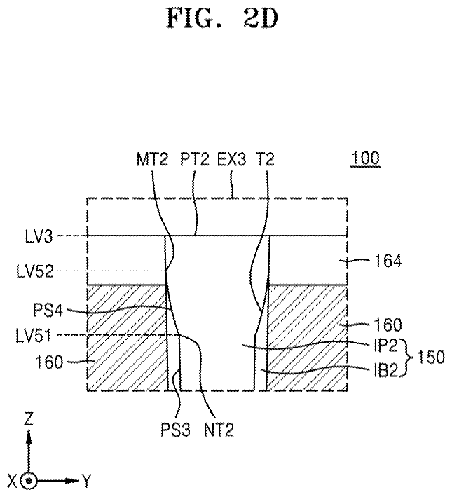

FIG. 1 is a plan layout diagram of an integrated circuit (IC) device 100 according to embodiments. FIG. 2A is a cross-sectional view taken along line X1-X1′ of FIG. 1. FIG. 2B is a cross-sectional view taken along line Y1-Y1′ of FIG. 1. FIG. 2C is an enlarged cross-sectional view of local area “EX2” of FIG. 2A. FIG. 2D is an enlarged cross-sectional view of local area “EX3” of FIG. 2B. The IC device 100 includes a field-effect transistor (FET) that includes a gate-all-around structure that includes an active region of a nanowire or nanosheet type and a gate that surrounds the active region, and is described with reference to FIGS. 1 and 2A to 2D.

Referring to FIGS. 1 and 2A to 2D, in an embodiment, the IC device 100 includes a substrate 102 that includes a first device region AR1, a second device region AR2 and a plurality of fin-type active regions F1 that protrude from the first device region AR1 and the second device region AR2 of the substrate 102 in the vertical direction (Z direction). The plurality of fin-type active regions F1 extend parallel to each other in a first lateral direction (X direction) and are spaced apart from each other in a second lateral direction (Y direction) that crosses the first lateral direction (X direction).

The substrate 102 includes a semiconductor, such as one of silicon (Si) or germanium (Ge), or a compound semiconductor, such as at least one of silicon germanium (SiGe), silicon carbide (SiC), gallium arsenide (GaAs), indium arsenide (InAs), indium gallium arsenide (InGaAs), or indium phosphide (InP). As used herein, the terms “SiGe,” “SiC,” “GaAs,” “InAs,” “InGaAs,” and “InP” each refers to a material that includes the elements included therein, without referring to a chemical formula that represents a stoichiometric relationship. The substrate 102 includes a conductive region, such as a doped well or a doped structure.

A device isolation film 112 is disposed on the substrate 102 and faces both sidewalls of each of the plurality of fin-type active regions F1. The device isolation film 112 includes one of an oxide film, a nitride film, or a combination thereof.

A plurality of gate lines 160 that extend along in the second lateral direction (Y direction) are formed on the plurality of fin-type active regions F1. A plurality of nanosheet stacks NSS are disposed on respective fin top surfaces FT of the plurality of fin-type active regions F1 in regions where the plurality of fin-type active regions F1 intersect with the plurality of gate lines 160. The plurality of nanosheet stacks NSS are spaced apart from the plurality of fin-type active regions F1 in the vertical direction (Z direction) and face the fin top surface FT of each of the plurality of fin-type active regions F1. As used herein, the term “nanosheet” refers to a conductive structure that has a cross-section that is substantially perpendicular to a direction in which current flows. The nanosheet may be interpreted as including a nanowire.

Each of the plurality of nanosheet stacks NSS includes a first nanosheet N1, a second nanosheet N2, and a third nanosheet N3 that overlap each other in the vertical direction (Z direction) on the fin top surface FT of the fin-type active region F1. The first to third nanosheets N1, N2, and N3 are located at different vertical distances (Z-directional distances) from the fin top surface FT of the fin-type active region F1. The number of nanosheet stacks NSS and the number of gate lines 160 on the fin top surface FT of the fin-type active region F1 are not specifically limited. For example, at least one nanosheet stack NSS and at least one gate line 160 are disposed on one fin-type active region F1.

Each of the plurality of nanosheet stacks NSS is illustrated as including three nanosheets, e.g., the first to third nanosheets N1, N2, and N3, in FIGS. 2A and 2B, but embodiments of the inventive concept are not necessarily limited thereto, and the number of nanosheets included in one nanosheet stack NSS is not specifically limited. For example, in other embodiments, each of the plurality of nanosheet stacks NSS includes one, two, or four or more nanosheets. Each of the first nanosheet N1, the second nanosheet N2, and the third nanosheet N3 has a channel region. In embodiments, the first to third nanosheets N1, N2, and N3 have substantially the same thicknesses as each other in the vertical direction (Z direction). In other embodiments, at least some of the first to third nanosheets N1, N2, and N3 have different thicknesses from each other in the vertical direction (Z direction).

In embodiments, the first to third nanosheets N1, N2, and N3 in one nanosheet stack NSS have the same sizes as each other in the first lateral direction (X direction). In other embodiments, at least some of the first to third nanosheets N1, N2, and N3 in one nanosheet stack NSS have different sizes from each other in the first lateral direction (X direction). For example, each of the first and second nanosheets N1 and N2 that are relatively close to the fin top surface FT of the fin-type active region F1 have a greater length in the first lateral direction (X direction) than the third nanosheet N3 that is farthest from the fin top surface FT of the fin-type active region F1.

In the first device region AR1 and the second device region AR2, a plurality of recesses R1 are formed in a top surface of each of the plurality of fin-type active regions F1. FIG. 2A illustrates an example in which a lowermost surface of each of the plurality of recesses R1 is located at a lower level than the fin top surface FT of each of the plurality of fin-type active regions F1, but embodiments of the inventive concept are not necessarily limited thereto. In some embodiments, the lowermost surface of each of the plurality of recesses R1 is at substantially the same level as the fin top surface FT of the fin-type active region F1. A plurality of source/drain regions 130 are formed on the plurality of recesses R1.

In the first device region AR1 and the second device region AR2, the plurality of gate lines 160 extend along the second lateral direction (Y direction) on the plurality of fin-type active regions F1 and the device isolation film 112. The plurality of gate lines 160 surround each of the first to third nanosheets N1, N2, and N3 in each of the plurality of nanosheet stacks NSS while covering the plurality of nanosheet stacks NSS on the plurality of fin-type active regions F1. A plurality of transistors TR are respectively formed on the substrate 102 at intersections between the plurality of fin-type active regions F1 and the plurality of gate lines 160. In embodiments, the first device region AR1 is an NMOS transistor region and the second device region AR2 is a PMOS transistor region. A plurality of NMOS transistors are formed at intersections between the fin-type active region F1 and the plurality of gate lines 160 in the first device region AR1, and a plurality of PMOS transistors are formed at intersections between the fin-type active region F1 and the plurality of gate lines 160 in the second device region AR2. In other embodiments, each of the first device region AR1 and the second device region AR2 is an NMOS transistor region. In still other embodiments, each of the first device region AR1 and the second device region AR2 is a PMOS transistor region.

As shown in FIGS. 2A and 2B, in an embodiment, each of the plurality of gate lines 160 includes a main gate portion 160M and a plurality of sub-gate portions 160S. The main gate portion 160M covers a top surface of the nanosheet stack NSS and extend along the second lateral direction (Y direction). The plurality of sub-gate portions 160S are integrally connected to the main gate portion 160M and arranged one-by-one between the first to third nanosheets N1, N2, and N3 and between the fin-type active region F1 and the first nanosheet N1.

Each of the plurality of gate lines 160 includes at least one of a metal, a metal nitride, a metal carbide, or a combination thereof. The metal is at least one of titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), or palladium (Pd). The metal nitride is one of titanium nitride (TiN) or tantalum (TaN). The metal carbide is titanium aluminum carbide (TiAlC). In embodiments, each of the plurality of gate lines 160 has a structure in which a metal nitride film, a metal film, a conductive capping film, and a gap-fill metal film are sequentially stacked. The metal nitride film and the metal film include at least one of titanium (Ti), tantalum (Ta), tungsten (W), ruthenium (Ru), niobium (Nb), molybdenum (Mo), or hafnium (Hf). The gap-fill metal film includes at least one of tungsten (W), aluminum (Al), or a combination thereof. Each of the plurality of gate lines 160 includes at least one work-function metal-containing film. The at least one work-function metal-containing film includes at least one of Ti, W, Ru, Nb, Mo, Hf, Ni, Co, Pt, Yb, Tb, Dy, Er, or Pd. In embodiments, each of the plurality of gate lines 160 has a stack structure of at least two layers of a first work-function metal-containing film, a second work-function metal-containing film, or a gap-fill metal film. For example, the first work-function metal-containing film includes a titanium nitride (TiN) film. The second work-function metal-containing film includes a combination of a first TiN film, a titanium aluminum carbide (TiAlC) film, and a second TiN film. In embodiments, each of the plurality of gate lines 160 includes one of a TiN film, a stack structure of TiAlC/TiN/W, a stack structure of TiN/TaN/TiAlC/TiN/W, or a stack structure of TiN/TaN/TiN/TiAlC/TiN/W. However, a constituent material of each of the plurality of gate lines 160 is not necessarily limited to the examples described above and can vary in other embodiments of the inventive concept.

In embodiments, the plurality of gate lines 160 have the same stack structures as each other in the first device region AR1 and the second device region AR2. In other embodiments, the plurality of gate lines 160 have different stack structures from each other in the first device region AR1 and the second device region AR2.

As shown in FIGS. 1 and 2B, the plurality of gate lines 160 include a pair of gate lines 160 that are collinear with each other in the second lateral direction (Y direction) and spaced apart from each other in the second lateral direction (Y direction). Of the pair of gate lines 160, a gate line 160 in the first device region AR1 is disposed on the fin-type active region F1 and extends along the second lateral direction (Y direction). Of the pair of gate lines 160, a gate line 160 in the second device region AR2 is disposed on the fin-type active region F1 and extends along the second lateral direction (Y direction). The gate line 160 in the second device region AR2 is spaced apart in the second lateral direction (Y direction) from the gate line 160 in the first device region AR1, and extends in the second lateral direction (Y direction) along an extension line of the first gate line 160, which is in the first device region AR1.

As shown in FIGS. 1 and 2A, in an embodiment, a fin isolation insulating portion 190 is disposed between a pair of fin-type active regions F1 that are collinear with each other in the first lateral direction (X direction). The fin isolation insulating portion 190 extends in the second lateral direction (X direction) and passes between each of a plurality of fin-type active regions F1 that are collinear with each other in the first lateral direction (X direction). The fin isolation insulating portion 190 has a line-shaped structure that extends parallel to the plurality of gate lines 160 in the second lateral direction (Y direction). A distance in the first lateral direction (X direction) between one gate line 160 adjacent to one side of the fin isolation insulating portion 190 is substantially equal to a distance in the first lateral direction (X direction between another gate line 160 adjacent to the other side of the fin isolation insulating portion 190

The fin isolation insulating portion 190 are disposed between a pair of source/drain regions 130 that are disposed on the pair of fin-type active regions F1 that are collinear in the first lateral direction (X direction). One source/drain region 130 is disposed between the fin isolation insulating portion 190 and an adjacent gate line 160.

As shown in FIGS. 1 and 2B, in an embodiment, the first device region AR1 and the second device region AR2 are spaced apart from each other with a gate isolation area CTA interposed therebetween in the second lateral direction (Y direction). The gate line 160 in the first device region AR1 is spaced apart from the gate line 160 in the second device region AR2 with a gate cut insulating portion 150 located in the gate isolation area CTA therebetween. In the first device region AR1 and the second device region AR2, each of the plurality of gate lines 160 adjacent to the gate cut insulating portion 150 is in contact with the gate cut insulating portion 150. The gate cut insulating portion 150 extends in the first lateral direction (X direction) in the gate isolation area CTA. As can be seen from region “EX1” of FIG. 1, the gate cut insulating portion 150 is integrally connected to the fin isolation insulating portion 190.

As shown in FIGS. 2A and 2B, in an embodiment, in the first device region AR1 and the second device region AR2, a gate dielectric film 152 is interposed between the first to third nanosheets N1, N2, and N3 of the plurality of nanosheet stacks NSS and the gate lines 160. The gate dielectric film 152 includes portions that cover respective surfaces of the first nanosheet N1, the second nanosheet N2, and the third nanosheet N3, and portions that cover sidewalls of the main gate portion 160M. The gate dielectric film 152 is not interposed between the gate line 160 and the gate cut insulating portion 150.

In embodiments, the gate dielectric film 152 includes a stack structure of an interfacial film and a high-k dielectric film. The interfacial film includes a low-k dielectric material film that has a dielectric constant of about 9 or less, such as one of a silicon oxide film, a silicon oxynitride film, or a combination thereof. In embodiments, the interfacial film is omitted. The high-k dielectric film includes a material that has a higher dielectric constant than a silicon oxide film. For example, the high-k dielectric film has a dielectric constant of about 10 to about 25. The high-k dielectric film includes hafnium oxide, without necessarily being limited thereto. In embodiments, the gate dielectric film 152 in the first device region AR1 has the same structure as the gate dielectric film 152 in the second device region AR2. In other embodiments, the gate dielectric film 152 in the first device region AR1 has a different structure from that of the gate dielectric film 152 in the second device region AR2.

In each of the first device region AR1 and the second device region AR2, the first to third nanosheets N1, N2, and N3 each includes a semiconductor layer that includes the same elements as each other. In embodiments, each of the first nanosheet N1, the second nanosheet N2, and the third nanosheet N3 includes a silicon (Si) layer. In embodiments, the first to third nanosheets N1, N2, and N3 are doped with a dopant of the same conductivity type as that of the source/drain region 130 that is in contact with the first to third nanosheets N1, N2, and N3. For example, the first to third nanosheets N1, N2, and N3 each includes a Si layer doped with an n-type dopant in the first device region AR1, and the first to third nanosheets N1, N2, and N3 each includes a Si layer doped with a p-type dopant in the second device region AR2. In other embodiments, the source/drain region 130 in the first device region AR1 has the same conductivity type as the source/drain region 130 in the second device region AR2, and all of the first to third nanosheets N1, N2, and N3 include a Si layer doped with a dopant of the same conductivity type in the first device region AR1 and the second device region AR2.

As shown in FIG. 2B, in an embodiment, the device isolation film 112 includes a portion disposed between the fin-type active region F1 and the gate cut insulating portion 150 and a portion disposed between the substrate 102 and the gate cut insulating portion 150.

As shown in FIG. 2A, in an embodiment, both sidewalls of the plurality of gate lines 160 are respectively covered by a plurality of insulating spacers 118 on the plurality of fin-type active regions F1 and the device isolation film 112. Each of the plurality of insulating spacers 118 includes a portion that covers both sidewalls of the main gate portion 160M on the top surface of the nanosheet stack NSS and a portion that covers the gate line 160 on the device isolation film 112. Each of the plurality of insulating spacers 118 are spaced apart from the gate line 160 with the gate dielectric film 152 interposed therebetween. The plurality of insulating spacers 118 include at least one of silicon nitride, silicon oxide, silicon carbonitride (SiCN), silicon boron nitride (SiBN), silicon oxynitride (SiON), silicon oxycarbonitride (SiOCN), silicon boron carbonitride (SiBCN), silicon oxycarbide (SiOC), or a combination thereof. As used herein, the terms “SiCN,” “SiBN,” “SiON,” “SiOCN,” “SiBCN,” and “SiOC” each refers to a material that includes elements included therein, without referring to a chemical formula that represents a stoichiometric relationship.

As shown in FIG. 2A, in an embodiment, the sidewalls of each of the plurality of sub-gate portions 160S between the first to third nanosheets N1, N2, and N3 and between the fin-type active region F1 and the first nanosheet N1 are spaced apart from the source/drain region 130 with the gate dielectric film 152 interposed therebetween. Each of the plurality of source/drain regions 130 faces the nanosheet stack NSS and the plurality of sub-gate portions 160S in the first lateral direction (X direction). The gate dielectric film 152 includes a portion in contact with the source/drain region 130.

As shown in FIG. 2A, in an embodiment, the main gate portion 160M of the gate line 160 is spaced apart from the source/drain region 130 with the insulating spacer 118 interposed therebetween. In embodiments, the first device region AR1 is an NMOS transistor region and the second device region AR2 is a PMOS transistor region. For example, the plurality of source/drain regions 130 in the first device region AR1 include at least one of a Si layer doped with an n-type dopant or a SiC layer doped with an n-type dopant, and the plurality of source/drain regions 130 in the second device region AR2 include a SiGe layer doped with a p-type dopant. The n-type dopant is one of phosphorus (P), arsenic (As), or antimony (Sb). The p-type dopant is one of boron (B) or gallium (Ga).

The plurality of source/drain regions 130 in the first device region AR1 have different shapes and sizes from the plurality of source/drain regions 130 in the second device region AR2. However, embodiments of the inventive concept are not necessarily limited thereto, and a plurality of source/drain regions 130 that have various shapes and sizes can be formed in the first device region AR1 and the second device region AR2.

As shown in FIG. 2A, in an embodiment, the plurality of source/drain regions 130 are covered by an insulating liner 142. The insulating liner 142 conformally covers respective surfaces of the plurality of source/drain regions 130 and the insulating spacers 118. The insulating liner 142 includes at least one of SiN, SiCN, SiBN, SiON, SiOCN, SiBCN, SiOC, SiO₂, or a combination thereof. The insulating liner 142 is covered by an inter-gate dielectric film 144. The inter-gate dielectric film 144 includes at least one of a silicon oxide film, a silicon nitride film, SiON, SiOCN, or a combination thereof.

As shown in FIGS. 2A and 2B, in an embodiment, a top surface of each of the gate line 160, the gate dielectric film 152, insulating spacer 118, the insulating liner 142, and the inter-gate dielectric film 144 is covered by a capping insulating layer 164. The capping insulating layer 164 includes one of a silicon nitride film or a SiCN film. A top surface of the capping insulating layer 164, a top surface of the gate cut insulating portion 150, and a top surface of the fin isolation insulating portion 190 are coplanar with each other.

As shown in FIG. 2A, in an embodiment, a bottom surface of the fin isolation insulating portion 190 is spaced apart from a main surface 102M of the substrate 102 in the vertical direction (Z direction). A first vertical distance L1 between the vertical level LV0 of the main surface 102M of the substrate 102 and the vertical level LV1 of the bottom surface of the fin isolation insulating portion 190 is greater than 0.

As shown in FIG. 2B, in an embodiment, a bottom surface of the gate cut insulating portion 150 is spaced apart in the vertical direction (Z direction) from the main surface 102M of the substrate 102 with the device isolation film 112 interposed therebetween. A second vertical distance L2 between the vertical level LV0 of the main surface 102M of the substrate 102 and the vertical level LV2 of the bottom surface of the gate cut insulating portion 150 is greater than 0. As used herein, the term “vertical level” refers to a distance from the main surface 102M of the substrate 102 in the vertical direction (Z direction or −Z direction).

In embodiments, a width of the fin isolation insulating portion 190 in the first lateral direction (X direction) is greater than a width of the gate cut insulating portion 150 in the second lateral direction (Y direction). In the vertical direction (Z direction), a length of the fin isolation insulating portion 190 is greater than a length of the gate cut insulating portion 150. The first vertical distance L1 0 is less than the second vertical distance L2.

As shown in FIGS. 2A and 2C, in an embodiment, the fin isolation insulating portion 190 passes through the capping insulating layer 164 in the vertical direction (Z direction) between the pair of collinear fin-type active regions F1 in the first lateral direction (X direction). The fin isolation insulating portion 190 includes an isolation insulating plug IP1 and an isolation insulating liner IB1 that surrounds a bottom surface and a sidewall of the isolation insulating plug IP1.

The isolation insulating plug IP1 includes a portion, hereinafter referred to as “a first portion”, that is interposed between the pair of collinear fin-type active regions F1 in the first lateral direction (X direction), and a portion, hereinafter referred to as “a second portion”, that is integrally connected to the first portion and passes through the capping insulating layer 164 in the vertical direction (Z direction). An uppermost portion MT1 of the isolation insulating liner IB1 that is farthest from the substrate 102 is closer to the substrate 102 than an isolation insulating top surface PT1 of the isolation insulating plug IP1. In the first lateral direction (X direction), a greatest width of the second portion of the isolation insulating plug IP1 is greater than a greatest width of a portion of the isolation insulating plug IP1 that is covered by the isolation insulating liner IB1.

In embodiments, the isolation insulating liner IB1 includes one of a silicon nitride film or a SiCN film. The isolation insulating plug IP1 includes at least one of a silicon oxide film, a SiON film, a SiOCN film, a SiCN film, a silicon nitride film, or a combination thereof. For example, the isolation insulating liner IB1 includes a silicon nitride film and the isolation insulating plug IP1 includes a silicon oxide film. For example, the isolation insulating liner IB1 includes a SiCN film and the isolation insulating plug IP1 includes at least one of a SiON film, a SiOCN film, or a combination thereof. For example, the isolation insulating liner IB1 includes a SiCN film and the isolation insulating plug IP1 includes a silicon nitride film. In embodiments, when each of the isolation insulating liner IB1 and the capping insulating layer 164 includes a silicon nitride film, the isolation insulating plug IP1 includes a silicon oxide film.

The isolation insulating liner IB1 includes a chamfer top surface T1 that gradually extends into the fin isolation insulating portion 190 in the first lateral direction (X direction) as the chamfer top surface T1 extends from the uppermost portion MT1 of the isolation insulating liner IB1 toward the substrate 102. A portion of the isolation insulating liner IB1 that is located below the chamfer top surface T1 in the vertical direction (Z direction) has a first thickness in the first lateral direction (X direction) in a range of about 3 nm to about 7 nm. A portion of the isolation insulating liner IB1 that includes the chamfer top surface T1 has a second thickness in the first lateral direction (X direction) that is less than the first thickness.

The chamfer top surface T1 includes a curved surface. The isolation insulating plug IP1 includes a portion in contact with the chamfer top surface T1 and that overlaps the isolation insulating liner IB1 in the first direction (X-direction) and the vertical direction (Z direction).

The isolation insulating top surface PT1 of the isolation insulating plug IP1 is coplanar with the top surface of the capping insulating layer 164. The second portion of the isolation insulating plug IP1 that passes through the capping insulating layer 164 in the vertical direction (Z direction) has a sidewall in contact with the capping insulating layer 164.

A sidewall of the isolation insulating plug IP1 include a lower sidewall PS1 and an upper sidewall PS2. The lower sidewall PS1 is closer to the substrate 102 than the chamfer top surface T1 of the isolation insulating liner IB1. The upper sidewall PS2 is farther from the substrate 102 than the lower sidewall PS1. The lower sidewall PS1 of the isolation insulating plug IP1 extends from a chamfer end portion NT1 of the chamfer top surface T1 to a bottom surface of the isolation insulating plug IP1. The upper sidewall PS2 of the isolation insulating plug IP1 extends from the chamfer end portion NT1 to the isolation insulating top surface PT1 of the isolation insulating plug IP1. The upper sidewall PS2 of the isolation insulating plug IP1 is in contact with chamfer top surface T1 of the isolation insulating liner IB1. In the isolation insulating plug IP1, a slope of the lower sidewall PS1 differs from a slope of the upper sidewall PS2. A slope of the sidewall of the isolation insulating plug IP1 changes along a vertical direction (Z-direction). The slope of the sidewall of the isolation insulating plug IP1 along the upper sidewall PS2 has a greater variation than other portions of the sidewall of the isolation insulating plug IP1.

The chamfer end portion NT1 of the chamfer top surface T1 is located at a vertical level LV41 that is closer to the substrate 102 than a vertical level of the capping insulating layer 164. The uppermost portion MT1 of the chamfer top surface T1 is located at a vertical level LV42 that is closer to the substrate 102 than a vertical level LV3 of the top surface of the capping insulating layer 164.

As shown in FIGS. 2A to 2D, in an embodiment, the capping insulating layer 164 extends in a lateral direction, such as an X direction and a Y direction, and covers the top surface of each of the gate line 160, the gate dielectric film 152, the insulating spacer 118, the insulating liner 142, and the inter-gate dielectric film 144. The capping insulating layer 164 includes a portion that is spaced apart in the vertical direction (Z direction) from the source/drain region 130 with the insulating liner 142 and the inter-gate dielectric film 144 interposed therebetween. Each of the insulating liner 142 and the inter-gate dielectric film 144 includes a portion interposed between the gate line 160 and the fin isolation insulating portion 190 in the first lateral direction (X direction).

In the IC device 100, the fin isolation insulating portion 190, which is located in a fin isolation area that insulates adjacent transistors from each other, has a void-free reliable structure. Accordingly, the fin isolation area provided by the fin isolation insulating portion 190 has a stable structure that is free from structural defects, such as voids. For example, even when an area of a device region is downscaled and an aspect ratio of the fin isolation area increases, transistors that are adjacent to each other with the fin isolation insulating portion 190 interposed therebetween, are stably insulated from each other by the fin isolation insulating portion 190, and an undesired leakage current between the adjacent transistors is prevented from occurring. Accordingly, the plurality of transistors TR in the IC device 100 have optimum performance and the reliability of the IC device 100 increases.

As shown in FIGS. 1, 2B, and 2C, in an embodiment, the gate cut insulating portion 150 has a line-shaped structure that extends parallel to the plurality of fin-type active regions F1 in the first lateral direction (X direction). The gate cut insulating portion 150 passes through the capping insulating layer 164 in the vertical direction (Z direction) between a pair of adjacent gate lines 160 in the second lateral direction (Y direction). The gate cut insulating portion 150 includes a cut insulating plug IP2 and a cut insulating liner IB2 that surrounds a bottom surface and a sidewall of the cut insulating plug IP2.

The cut insulating plug IP2 includes a portion, hereinafter referred to as “a third portion”, that is interposed between the pair of collinear gate lines 160 in the second lateral direction (Y direction), and a portion, hereinafter referred to as “a fourth portion”, that is integrally connected to the third portion and passes through the capping insulating layer 164 in the vertical direction (Z direction). An uppermost portion MT2 of the cut insulating liner IB2 that is farthest from the substrate 102 is closer to the substrate 102 than a cut insulating top surface PT2 of the cut insulating plug IP2. In the second lateral direction (Y direction), a greatest width of the fourth portion of the cut insulating plug IP2 is greater than a greatest width of a portion of the gate cut insulating portion 150 that is covered by the cut insulating liner IB2.

In embodiments, the cut insulating liner IB2 of the gate cut insulating portion 150 includes one of a silicon nitride film or a SiCN film. The cut insulating plug IP2 of the gate cut insulating portion 150 includes at least one of a silicon oxide film, a SiON film, a SiOCN film, a SiCN film, a silicon nitride film, or a combination thereof. For example, the cut insulating liner IB2 includes a silicon nitride film and the cut insulating plug IP2 includes a silicon oxide film. For example, the cut insulating liner IB2 includes a SiCN film and the cut insulating plug IP2 includes at least one of a SiON film, a SiOCN film, or a combination thereof. For example, the cut insulating liner IB2 includes a SiCN film and the cut insulating plug IP2 includes a silicon nitride film. In embodiments, when each of the cut insulating liner IB2 and the capping insulating layer 164 includes a silicon nitride film, the cut insulating plug IP2 includes a silicon oxide film.

The cut insulating plug IP2 of the gate cut insulating portion 150 and the isolation insulating plug IP1 of the fin isolation insulating portion 190 are integrally connected to each other and include the same materials as each other. The cut insulating liner 1B2 of the gate cut insulating portion 150 and the isolation insulating liner IB1 of the fin isolation insulating portion 190 are integrally connected to each other and include the same materials as each other. In embodiments, each of the cut insulating liner IB2 and the isolation insulating liner IB1 includes one of a silicon nitride film or a SiCN film. Each of the cut insulating plug IP2 and the isolation insulating plug IP1 includes at least one of a silicon oxide film, a SiON film, a SiOCN film, a SiCN film, a silicon nitride film, or a combination thereof. For example, each of the cut insulating liner IB2 and the isolation insulating liner IB1 includes a silicon nitride film, and each of the cut insulating plug IP2 and the isolation insulating plug IP1 includes a silicon oxide film, without necessarily being limited thereto.

As shown in FIGS. 2B and 2D, in an embodiment, the cut insulating liner IB2 includes a chamfer top surface T2 that gradually extends in the second lateral direction (Y direction) into the gate cut insulating portion 150 as the chamfer top surface T1 extends from the uppermost portion MT2 of the cut insulating liner IB2 toward the substrate 102. A portion of the cut insulating liner IB2 that is located below the chamfer top surface T2 in the vertical direction (Z direction) has a third thickness in the second lateral direction (Y direction) in a range of about 3 nm to about 7 nm. A portion of the cut insulating liner IB2 that includes the chamfer top surface T2 has a fourth thickness the second lateral direction (Y direction) that is less than the third thickness.

The cut insulating plug IP2 includes a portion in contact with the chamfer top surface T2 and that overlaps the cut insulating liner IB2 in the second lateral direction (Y direction) and the vertical direction (Z direction). The cut insulating top surface PT2 of the cut insulating plug IP2 is coplanar with the top surface of the capping insulating layer 164. Of the cut insulating plug IP2, the fourth portion that passes through the capping insulating layer 164 in the vertical direction (Z direction) has a sidewall in contact with the capping insulating layer 164. The uppermost portion MT2 of the cut insulating liner 1B2 is closer to the substrate 102 than the top surface of the capping insulating layer 164.

A sidewall of the cut insulating plug IP2 includes a lower sidewall PS3 and an upper sidewall PS4. The lower sidewall PS3 is closer to the substrate 102 than the chamfer top surface T2 of the cut insulating liner IB2. The upper sidewall PS4 is farther from the substrate 102 than the lower sidewall PS3. The lower sidewall PS3 of the cut insulating plug IP2 extends from a chamfer end portion NT2 of the chamfer top surface T2 to a bottom surface of the cut insulating plug IP2. The upper sidewall PS4 of the cut insulating plug IP2 extends from the chamfer end portion NT2 to the cut insulating top surface PT2 of the cut insulating plug IP2. In the cut insulating plug IP2, a slope of the lower sidewall PS3 differs from a slope of the upper sidewall PS4. A slope of the sidewall of the cut insulating plug IP2 changes along a vertical direction (Z-direction). The slope of the sidewall of the cut insulating plug IP2 along the upper sidewall PS4 has a greater variation than other portions of the sidewall of the cut insulating plug IP2.

The chamfer end portion NT2 of the chamfer top surface T2 is located at a vertical level LV51 that is closer to the substrate 102 than a vertical level of the capping insulating layer 164. The uppermost portion MT2 of the chamfer top surface T2 is located at a vertical level LV52 that is closer to the substrate 102 than a vertical level of the top surface of the capping insulating layer 164.

As shown in FIG. 2B, in an embodiment, a height in the vertical direction (Z direction) of the gate cut insulating portion 150 is greater than a height of each of the plurality of gate lines 160. A vertical level LV2 of the bottom surface of the gate cut insulating portion 150 is located closer to the substrate 102 than a vertical level of a bottom surface of each of the plurality of gate lines 160. The vertical level LV2 of the bottom surface of the gate cut insulating portion 150 is located higher than a vertical level LV0 of the main surface 102M of the substrate 102 and lower than a vertical level of a lowermost surface of the gate line 160.

As shown in FIGS. 1 and 2B, in an embodiment, in the second lateral direction (Y direction), one of the sidewalls of the gate cut insulating portion 150 faces the gate line 160 in the first device region AR1, while the other sidewall faces the gate line 160 in the second device region AR2. The gate cut insulating portion 150 extends parallel to the pair of fin-type active regions F1 in the first lateral direction (X direction) between a pair of fin-type active regions F1 that are adjacent to each other in the second lateral direction (Y direction). A lower portion of the gate cut insulating portion 150 passes into a portion of the device isolation film 112 in the vertical direction (Z direction). The device isolation film 112 surrounds the lower portion of the gate cut insulating portion 150.

A pair of gate lines 160 that are adjacent to each other in the second lateral direction (Y direction) on both sides of the gate cut insulating portion 150 are not connected to each other but are spaced apart from each other. The plurality of gate lines 160 are arranged in a line in the second lateral direction (Y direction) and are spaced apart in the first lateral direction (X direction) from each other by the gate cut insulating portion 150. A length of at least one of the gate lines 160 in the second lateral direction (Y direction) is defined by the gate cut insulating portion 150.

A pair of gate lines 160 that are adjacent to each other in the second lateral direction (Y direction) are located on both sides of the gate cut insulating portion 150 and include a sidewall in contact with the cut insulating liner IB2.

In the IC device 100 described with reference to FIGS. 1 and 2A to 2D, the fin isolation insulating portion 190 that insulates adjacent transistors from each other has a void-free reliable structure. Accordingly, the fin isolation insulating portion 190 has a stable structure free from structural defects, such as voids. For example, even when an area of a device region is reduced by downscaling and an aspect ratio of the fin isolation area increases, transistors that are adjacent to each other with the fin isolation insulating portion 190 therebetween are securely insulated from each other by the fin isolation insulating portion 190, and an undesired leakage current between the adjacent transistors is prevented from occurring. Accordingly, the plurality of transistors TR in the IC device 100 provide optimum performance and the reliability of the IC device 100 increases.

Furthermore, the IC device 100 includes a gate cut insulating portion 150 between the gate line 160 located in the first device region AR1 and the gate line 160 located in the second device region AR2, and the gate cut insulating portion 150 is integrally connected to the fin isolation insulating portion 190. The gate cut insulating portion 150 has a stable structure free from structural defects, such as voids.

In a comparative example, when the cut insulating liner IB2 is omitted from the gate cut insulating portion 150, the cut insulating plug IP2 of the gate cut insulating portion 150 is in direct contact with the sidewall of the gate line 160 over the total vertical length of the sidewall of the gate line 160. As a result, a portion of the gate line 160 that is adjacent to the gate cut insulating portion 150 can undesirably oxidize. In an embodiment, in the IC device 100, the gate cut insulating portion 150 includes a cut insulating liner 1B2 that surrounds the sidewall and the bottom surface of the cut insulating plug IP2, and the cut insulating plug IP2 includes a silicon nitride film. Accordingly, even when the gate cut insulating portion 150 is in direct contact with the gate line 160, the gate line 160 is in contact with the cut insulating liner 1B2 of the gate cut insulating portion 150. Thus, undesired oxidation of a portion of the gate line 160 that is adjacent to the gate cut insulating portion 150 and consequent deterioration of the IC device 100 is prevented.

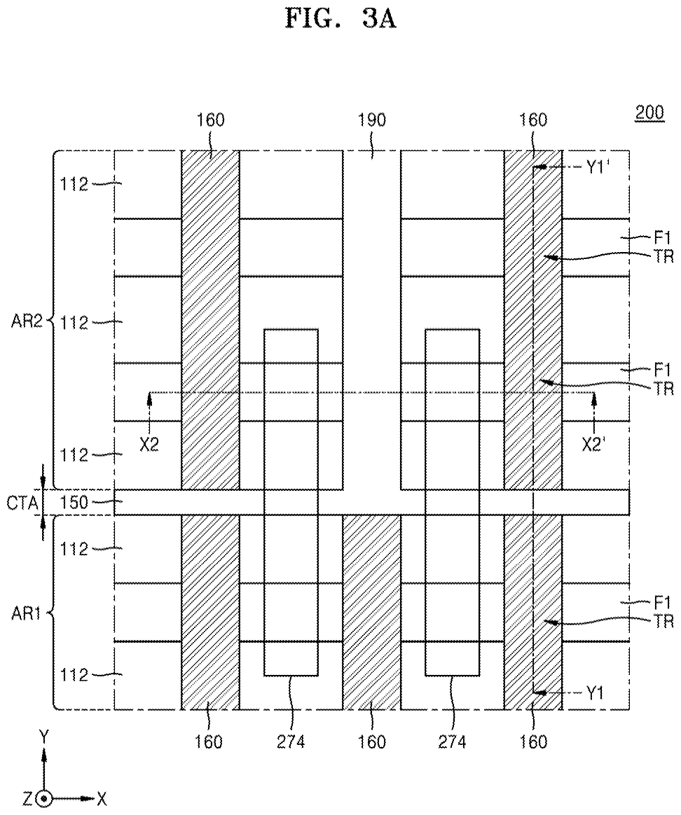

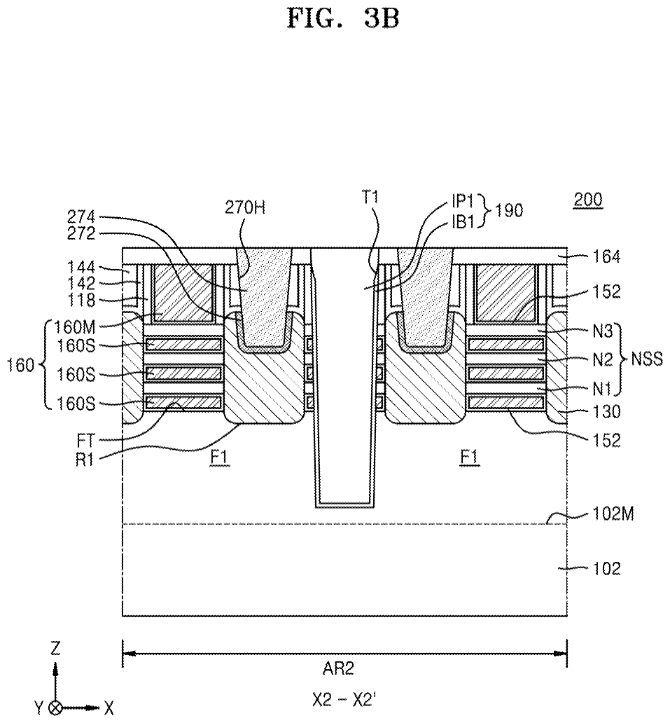

FIGS. 3A and 3B illustrate an IC device 200 according to embodiments. FIG. 3A is a plan layout diagram of the IC device 200 according to embodiments, and FIG. 3B is a cross-sectional view taken along line X2-X2′ of FIG. 3A. In FIGS. 3A and 3B, the same reference numerals may be used to denote the same elements as in FIGS. 1 and 2A to 2D, and repeated descriptions thereof may be omitted.

Referring to FIGS. 3A and 3B, in an embodiment, the IC device 200 has substantially the same configuration as the IC device 100 described with reference to FIGS. 1 and 2A to 2D. However, the IC device 200 further includes a metal silicide film 272 and a source/drain contact 274. The metal silicide film 272 is in contact with the source/drain region 130 on the source/drain region 130. The source/drain contact 274 is disposed inside a contact hole 270H that passes through the capping insulating layer 164, the inter-gate dielectric film 144, and the insulating liner 142 in the vertical direction (Z direction).

The source/drain contact 274 is in contact with the metal silicide film 272. The metal silicide film 272 is interposed between the source/drain region 130 and the source/drain contact 274. The source/drain contact 274 is connected to the source/drain region 130 through the metal silicide film 272. The source/drain contact 274 passes into a portion of the source/drain region 130 in the vertical direction (Z direction). The capping insulating layer 164, the insulating liner 142, and the inter-gate dielectric film 144 surround a sidewall of the source/drain contact 274.

As shown in FIG. 3A, in an embodiment, the source/drain contact 274 has a planar shape that extend in the second lateral direction (Y direction), passes through a portion of the gate cut insulating portion 150 and intersects the gate cut insulating portion 150.

The metal silicide film 272 includes at least one of Ti, W, Ru, Nb, Mo, Hf, Ni, Co, Pt, Yb, Tb, Dy, Er, or Pd. For example, the metal silicide film 272 includes titanium silicide. In embodiments, the source/drain contact 274 includes a conductive barrier film and a metal plug surrounded by the conductive barrier film. The conductive barrier film includes at least one of Ti, Ta, TiN, TaN, or a combination thereof, and the metal plug includes at least one of W, Co, Mo, Cu, Ru, Mn, or a combination thereof, without necessarily being limited thereto. In other embodiments, the source/drain contact 274 does not include a conductive barrier film.

In the IC device 200 described with reference to FIGS. 3A and 3B, similar to the IC device 100 described with reference to FIGS. 1 and 2A to 2D, each of the fin isolation insulating portion 190 and the gate cut insulating portion 150 has a stable structure free from structural defects, such as voids. Thus, an undesired leakage current between adjacent transistors can be prevented from occurring. Accordingly, a plurality of transistors TR in the IC device 200 provide optimum performance and the reliability of the IC device 200 is increased.

In addition, in the IC device 200, the cut insulating plug IP2 of the gate cut insulating portion 150 and the isolation insulating plug IP1 of the fin isolation insulating portion 190 are integrally connected to each other and include the same materials as each other, and a cut insulating liner IB2 of the gate cut insulating portion 150 and the isolation insulating liner IB1 of the fin isolation insulating portion 190 are integrally connected to each other and include the same materials as each other. For example, in the fin isolation insulating portion 190 and the gate cut insulating portion 150, the isolation insulating plug IP1 and the cut insulating plug IP2 each include a silicon oxide film, and the isolation insulating liner IB1 and the cut insulating liner IB2 each include a silicon nitride film. For example, as shown in FIG. 3A, even when the source/drain contact 274 has a planar shape that extends in the second lateral direction (Y direction), passes through a portion of the gate cut insulating portion 150 and intersects the gate cut insulating portion 150, a process of forming the contact hole 270H required for forming the source/drain contact 274 is facilitated. In addition, the gate cut insulating portion 150 has a stable structure free from structural defects, such as voids. Accordingly, during the formation of the source/drain contact 274, metals required for forming the source/drain contact 274 are prevented from penetrating into the gate line 160 adjacent thereto through a weak portion of the gate cut insulating portion 150 that undesirably intersects the source/drain contact 274. Accordingly, an undesired short circuit between the source/drain contact 274 and the gate line 160 adjacent thereto can be prevented from occurring.

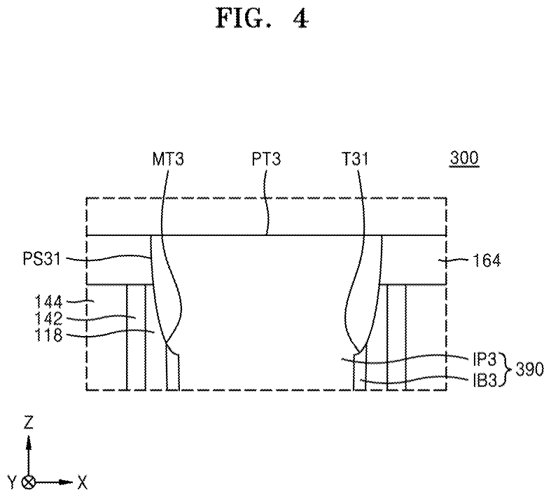

FIG. 4 is a cross-sectional view of an IC device 300 according to embodiments. FIG. 4 is an enlarged cross-sectional view of area “EX2” of FIG. 2A in the IC device 300. In FIG. 4, the same reference numerals may denote the same elements as in FIGS. 1 and 2A to 2D, and repeated descriptions thereof may be omitted.

Referring to FIG. 4, in an embodiment, the IC device 300 has substantially the same configuration as the IC device 100 described with reference to FIGS. 1 and 2A to 2D. However, the IC device 300 includes a fin isolation insulating portion 390.

The fin isolation insulating portion 390 has substantially the same configuration as the fin isolation insulating portion 190 described with reference to FIGS. 1 and 2A to 2C. However, the fin isolation insulating portion 390 includes an isolation insulating plug IP3 and an isolation insulating liner IB3 that surrounds a bottom surface and a sidewall of the isolation insulating plug IP3.

The isolation insulating liner 1B3 includes a chamfer top surface T31 that gradually extends into the fin isolation insulating portion 390 in the first lateral direction (X direction) as the chamfer top surface T31 extends in the vertical direction (Z direction) from an uppermost portion MT3 of the isolation insulating liner IB3 toward the substrate 102. The uppermost portion MT3 of the chamfer top surface T31 is located closer to the substrate 102 than an isolation insulating top surface PT3 of the isolation insulating plug IP3. In the first lateral direction (X direction), a greatest width of a portion of the isolation insulating plug IP3 that passes through the capping insulating layer 164 in the vertical direction (Z direction) is greater than a greatest width of a portion of the fin isolation insulating portion 390 that is covered by the isolation insulating liner IB3.

The chamfer top surface T31 of the isolation insulating liner 1B3 has a curved surface. The isolation insulating plug IP3 includes a portion in contact with the chamfer top surface T31 and that overlaps the isolation insulating liner IB3 in the vertical direction (Z direction) and the first lateral direction (X direction).

The isolation insulating top surface PT3 of the isolation insulating plug IP3 is coplanar with the top surface of the capping insulating layer 164. The portion of the isolation insulating plug IP3 that passes through the capping insulating layer 164 in the vertical direction (Z direction) has a sidewall PS31 in contact with the capping insulating layer 164. The portion of the isolation insulating plug IP3 that passes through the capping insulating layer 164 in the vertical direction (Z direction) may protrude further outward from the fin isolation insulating portion 390 than the isolation insulating liner IB3 in the first lateral direction (X direction). Details of the isolation insulating plug IP3 and the isolation insulating liner IB3 are substantially the same as those of the isolation insulating plug IP1 and the isolation insulating liner IB1 described with reference to FIGS. 2A to 2D.

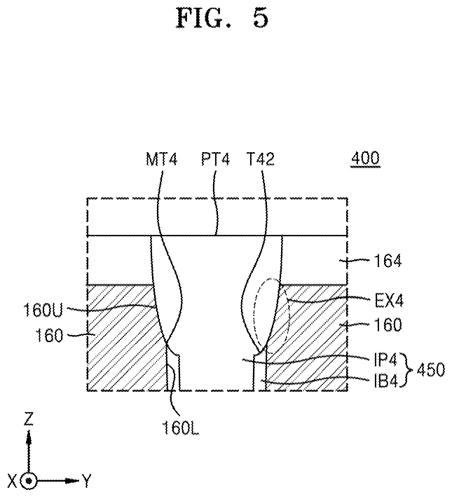

FIG. 5 is a cross-sectional view of an IC device 400 according to embodiments. FIG. 5 is an enlarged cross-sectional view of area “EX3” of FIG. 2B in the IC device 400. In FIG. 5, the same reference numerals may be used to denote the same elements as in FIGS. 1 and 2A to 2D, and repeated descriptions thereof may be omitted.

Referring to FIG. 5, in an embodiment, the IC device 400 has substantially the same configuration as the IC device 100 described with reference to FIGS. 1 and 2A to 2D. However, the IC device 400 includes a gate cut insulating portion 450.

The gate cut insulating portion 450 passes through a capping insulating layer 164 in the vertical direction (Z direction) between a pair of collinear gate lines 160 in the second lateral direction (Y direction). The gate cut insulating portion 450 includes a cut insulating plug IP4 and a cut insulating liner 1B4 that covers a bottom surface and surrounds a sidewall of the cut insulating plug IP4.

The cut insulating plug IP4 includes a portion located between the pair of collinear gate lines 160 in the second lateral direction (Y direction), and a portion that pass through the capping insulating layer 164 in the vertical direction (Z direction). An uppermost portion MT4 of the cut insulating liner IB4 that is farthest from a substrate 102 is closer to the substrate 102 than a cut insulating top surface PT4 of the cut insulating plug IP4. In the second lateral direction (Y direction), a greatest width of a portion of the cut insulating plug IP4 that passes through the capping insulating layer 164 in the vertical direction (Z direction) is greater than a greatest width of a portion of the gate cut insulating portion 450 that is covered by the cut insulating liner IB4.

The cut insulating liner IB4 includes a chamfer top surface T42 that extends in the second lateral direction (Y direction) into the gate cut insulating portion 450 as the chamfer top surface T42 extends in the vertical direction (Z direction) from the uppermost portion MT4 of the cut insulating liner IB4 toward the substrate 102. The cut insulating plug IP4 includes a portion in contact with the chamfer top surface T42 and that overlaps the cut insulating liner IB4 in the vertical direction (Z direction) and the second lateral direction (Y direction).

The cut insulating top surface PT4 of the cut insulating plug IP4 is coplanar with a top surface of the capping insulating layer 164. A portion of the cut insulating plug IP4 that passes through the capping insulating layer 164 in the vertical direction (Z direction) has a sidewall in contact with the capping insulating layer 164. The uppermost portion MT4 of the cut insulating liner IB4 is closer to the substrate 102 than the top surface of the capping insulating layer 164.

A pair of gate lines 160 that are disposed on both sides of the gate cut insulating portion 450 in the second lateral direction (Y direction) each include a lower sidewall 160L in contact with the cut insulating liner IB4, and an upper chamfer surface 160U in contact with the cut insulating plug IP4. As can be seen from portion “EX4” of FIG. 5, the upper chamfer surface 160U of the gate line 160 includes a curved surface that is recessed into the gate line 160 from the lower sidewall 160L. The upper chamfer surface 160U of the gate line 160 also includes a curved surface.

The lower sidewall 160L of the gate line 160 is spaced apart from the cut insulating plug IP4 with the cut insulating liner IB4 interposed therebetween. As shown in FIG. 5, in which the cut insulating plug IP4 of the gate cut insulating portion 450 is in contact with the upper chamfer surface 160U of the gate line 160, even when the cut insulating plug IP4 includes a silicon oxide film, the portion of the cut insulating plug IP4 that is in contact with the gate line 160 is limited to the upper chamfer surface 160U of the sidewall of the gate line 160, excluding the lower sidewall 160L. When the cut insulating plug IP4 is in contact with only the upper chamfer surface 160U as described above, adverse effects due to oxidation of the gate line 160 caused contact with the cut insulating plug IP4 with the gate line 160, are insignificant.

In the second lateral direction (Y direction), a distance between the respective upper chamfer surfaces 160U of the pair of gate lines 160 is greater than a distance between the respective lower sidewalls 160L of the pair of gate lines 160. In the second lateral direction (Y direction) of the cut insulating plug IP4, a portion that faces the upper chamfer surface 160U of the gate line 160 and a portion that faces the capping insulating layer 164 each have a greater width than a portion of the cut insulating plug IP4 that faces the lower sidewall 160L of the gate line 160.

The cut insulating plug IP4 includes a portion that protrudes further outward in the second lateral direction (Y direction) from the gate cut insulating portion 450 than the cut insulating liner IB4. Details of the cut insulating plug IP4 and the cut insulating liner IB4 are substantially the same as those of the cut insulating plug IP2 and the cut insulating liner IB2 that have been described with reference to FIGS. 2A and 2C.

In the IC devices 300 and 400 described with reference to FIGS. 4 and 5, similar to the IC device 100 described with reference to FIGS. 1 and 2A to 2D, each of the fin isolation insulating portion 390 and the gate cut insulating portion 450 has a stable structure free from structural defects, such as voids. Thus, an undesired leakage current between adjacent transistors is prevented from occurring. Accordingly, a plurality of transistors TR in each of the IC devices 300 and 400 provide optimum performance, and the reliability of the IC devices 300 and 400 increases.

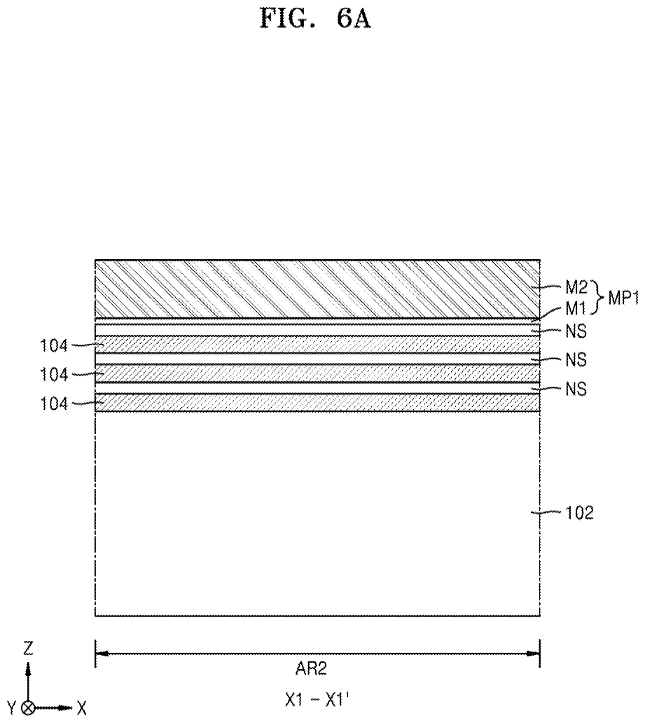

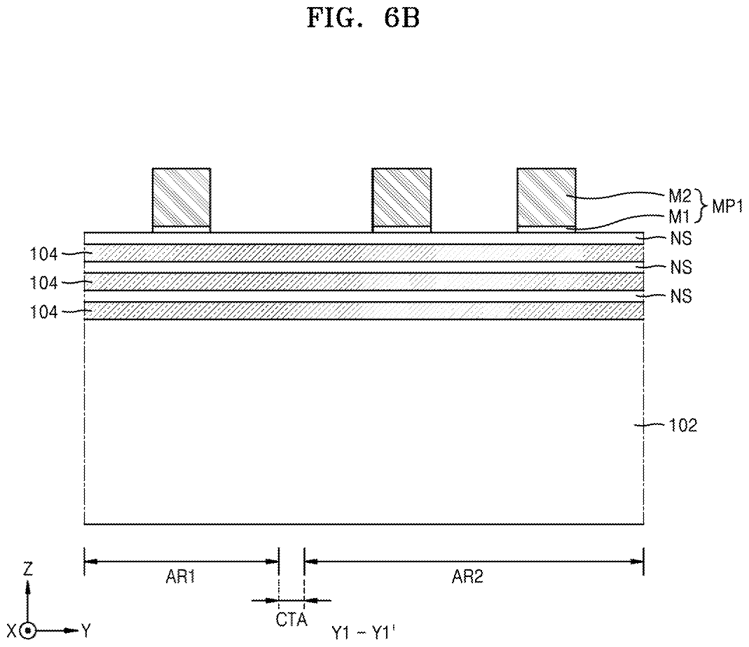

FIGS. 6A to 22B are cross-sectional views that illustrate a method of manufacturing an IC device, according to embodiments. FIGS. 6A, 9A, 10A, 11A, 12A, 13A, 14A, 15A, 16A, 17A, 18A, 19A, 20A, 21A, and 22A are cross-sectional views taken along line X1-X1′ of FIG. 1, FIGS. 6B, 7, 8, 9B, 10B, 11B, 12B, 13B, 14B, 15B, 16B, 17B, 18B, 19B, 20B, 21B, and 22B are cross-sectional views taken along line Y1-Y1′ of FIG. 1. An example of a method of manufacturing the IC device 100 shown in FIGS. 1 and 2A to 2D is described with reference to FIGS. 6A to 22B. In FIGS. 6A to 22B, the same reference numerals may be used to denote the same elements as in FIGS. 1 and 2A to 2D, and repeated descriptions thereof may be omitted.

Referring to FIGS. 6A and 6B, in an embodiment, a stack structure in which plurality of sacrificial semiconductor layers 104 and a plurality of nanosheet semiconductor layers NS are alternately stacked is formed on a substrate 102. Thereafter, a mask pattern MP1 is formed on the stack structure in a first device region AR1 and a second device region AR2. In embodiments, the mask pattern MP1 includes a two-layer structure of a silicon oxide film M1 and a silicon nitride film M2.

The plurality of sacrificial semiconductor layers 104 and the plurality of nanosheet semiconductor layers NS include semiconductor materials that have different etch selectivity's from each other. In embodiments, each of the plurality of nanosheet semiconductor layers NS includes a silicon (Si) layer and each of the plurality of sacrificial semiconductor layers 104 includes a silicon germanium (SiGe) layer. In embodiments, the plurality of sacrificial semiconductor layers 104 have a constant Ge content. The SiGe layer in the plurality of sacrificial semiconductor layers 104 have a constant Ge content that is in a range of about 5 at % to about 60 at %, for example, about 10 at % to about 40 at %. The Ge concentration of the SiGe layer in the plurality of sacrificial semiconductor layers 104 can be variously selected as needed.

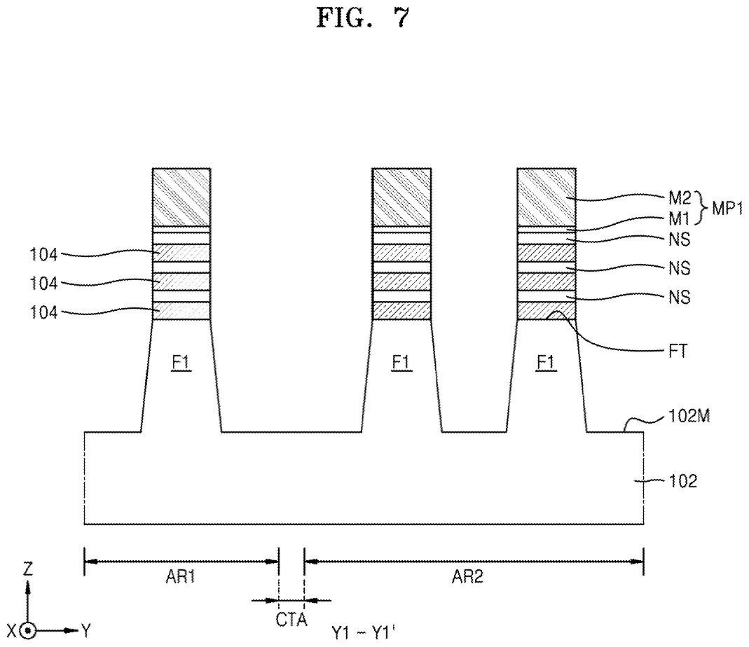

Referring to FIG. 7, in an embodiment, respective portions of the plurality of sacrificial semiconductor layers 104, the plurality of nanosheet semiconductor layers NS, and the substrate 102 are etched by using the mask pattern MP1 as an etch mask, and thus, a plurality of fin-type active regions F1 are formed. The plurality of fin-type active regions F1 protrude upward from the substrate 102 in the vertical direction (Z direction) and extend parallel to each other in a first lateral direction (X direction). The stack structure in which the plurality of sacrificial semiconductor layers 104 and the plurality of nanosheet semiconductor layers NS are alternately stacked and the mask pattern MP1 remains disposed on each of the plurality of fin-type active regions F1.

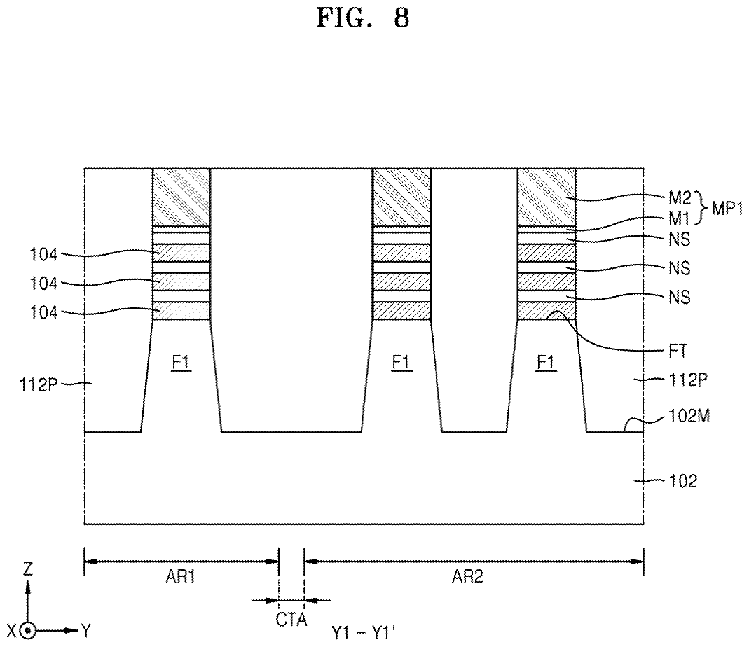

Referring to FIG. 8, in an embodiment, in the resultant structure of FIG. 7, a preliminary device isolation film 112P is formed that fills respective spaces between the plurality of fin-type active regions F1 and openings formed in the mask pattern MPL. The resultant structure includes the preliminary device isolation film 112P and is planarized by using a chemical mechanical polishing (CMP) process such that a top surface of the preliminary device isolation film 112P is coplanar with a top surface of the mask pattern MPL. A constituent material of the preliminary device isolation film 1120P is the same as that of the device isolation film 112 that has been described with reference to FIGS. 1 and 2B.

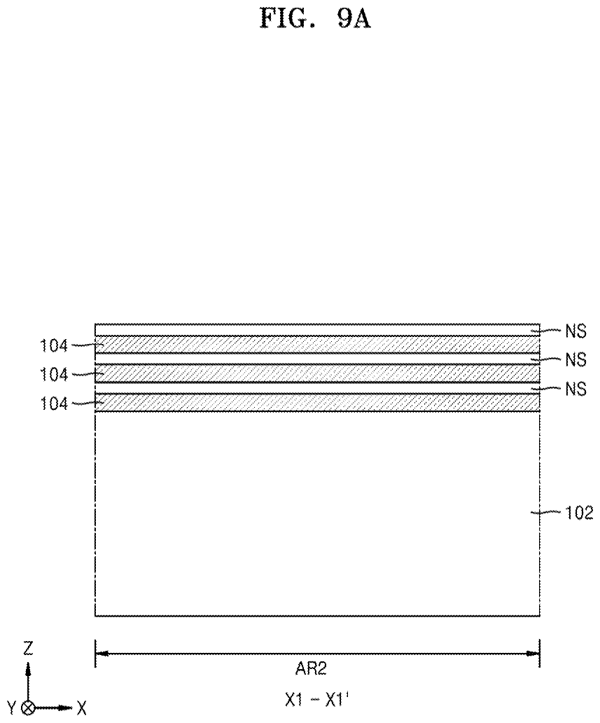

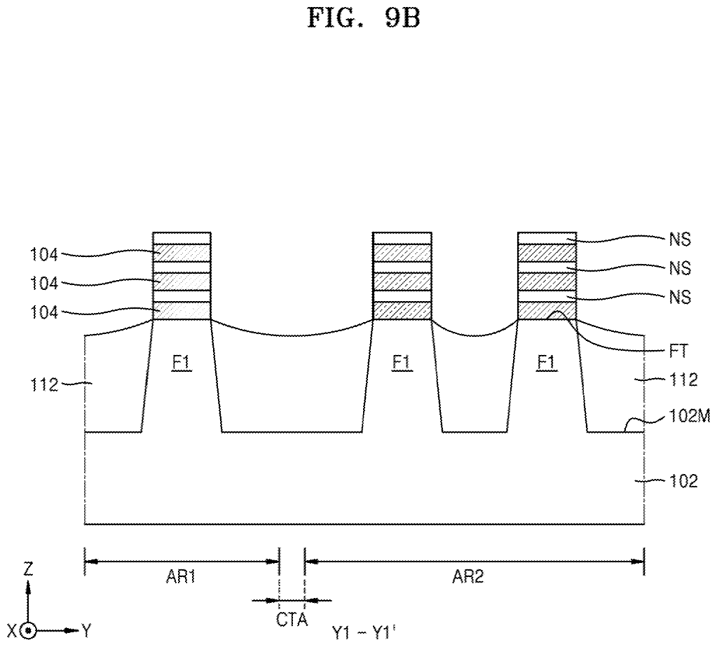

Referring to FIGS. 9A and 9B, in an embodiment, in the resultant structure of FIG. 8, a recess process is performed on the preliminary device isolation film 112P to form a device isolation film 112 that has a lowered top surface. The mask pattern MP1 is removed to expose a top surface of an uppermost nanosheet of the plurality of nanosheet semiconductor layers NS. A vertical level of an uppermost surface of the device isolation film 112 is that same as or lower than a vertical level of a fin top surface FT of each of the plurality of fin-type active regions F1.

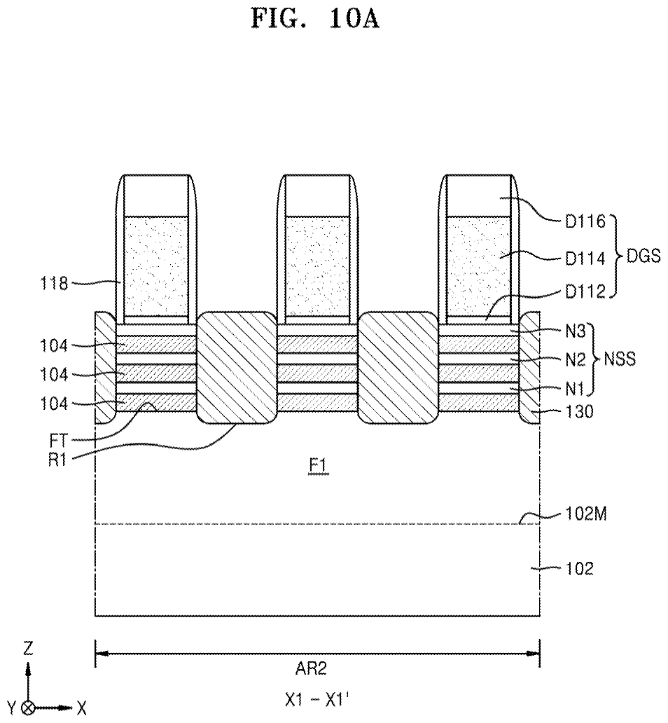

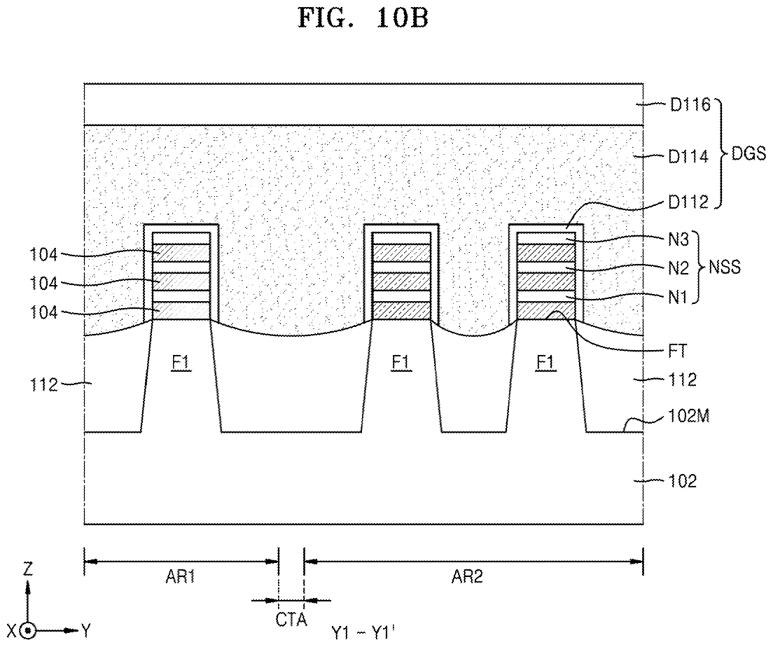

Referring to FIGS. 10A and 10B, in an embodiment, a plurality of dummy gate structures DGS and insulating spacers 118 are formed on the resultant structure of FIGS. 9A and 9B. The insulating spacers 118 cover both sidewalls of each of the plurality of dummy gate structures DGS. The plurality of dummy gate structures DGS are formed at positions that correspond to the plurality of gate lines 160 shown in FIG. 1A and continuously extend in the second lateral direction (Y direction).

Each of the plurality of dummy gate structures DGS includes an oxide film D112, a dummy gate layer D114, and a capping layer D116 that are sequentially stacked. In embodiments, the dummy gate layer D114 includes a polysilicon film, and the capping layer D116 includes a silicon nitride film.

As shown in FIG. 10A, in the first device region AR1 and the second device region AR2, respective portions of the plurality of sacrificial semiconductor layers 104 and the plurality of nanosheet semiconductor layers NS are removed by using the dummy gate structure DGS and the insulating spacers 118 as etch masks. Thus, a plurality of nanosheet stacks NSS are formed from the plurality of nanosheet semiconductor layers NS. Each of the plurality of nanosheet stacks NSS includes first to third nanosheets N1, N2, and N3.

In the first device region AR1 and the second device region AR2, part of the fin-type active region F1 exposed between each pair of adjacent nanosheet stacks NSS is etched, and thus, a plurality of first recesses R1 are formed in an upper portion of the fin-type active region F1. To form the plurality of first recesses R1, the fin-type active region F1 are etched by using a dry process, a wet process, or a combination thereof.

In the first device region AR1 and the second device region AR2, a plurality of source/drain regions 130 are formed on the fin-type active region F1 on both sides of each of the plurality of nanosheet stacks NSS. To form the plurality of source/drain regions 130, a semiconductor material is epitaxially grown from a surface of the fin-type active region F1 that is exposed at a bottom surface of each of the plurality of recesses R1, and a sidewall of each of the first to third nanosheets N1, N2, and N3.

In embodiments, to form the plurality of source/drain regions 130, one of a low-pressure chemical vapor deposition (LPCVD) process, a selective epitaxial growth (SEG) process, or a cyclic deposition and etching (CDE) process is performed by using source materials that include a semiconductor element precursor.

In embodiments, the process of forming the plurality of nanosheet stacks NSS, the process of forming the plurality of recesses R1, and the process of forming the plurality of source/drain regions 130 that are described above can be sequentially performed in an arbitrary order in the first device region AR1 and the second device region AR2. For example, after the processes of forming the plurality of nanosheet stacks NSS, forming the plurality of recesses R1, and forming the plurality of source/drain regions 130 are performed in the first device region AR1, the processes of forming the plurality of nanosheet stacks NSS, forming the plurality of recesses R1, and forming the plurality of source/drain regions 130 are performed in the second device region AR2. Alternatively, after the processes of forming the plurality of nanosheet stacks NSS, forming the plurality of recesses R1, and forming the plurality of source/drain regions 130 are performed in the second device region AR2, the processes of forming the plurality of nanosheet stacks NSS, forming the plurality of recesses R1, and forming the plurality of source/drain regions 130 are performed in the first device region AR1.

In embodiments, at least some of the plurality of source/drain regions 130 include a Si layer doped with an n-type dopant. For example, to form the plurality of source/drain regions 130, one or more of silane (SiH₄), disilane (Si₂H₆), trisilane (Si₃H₈), and/or dichlorosilane (SiH₂Cl₂) can be used as the Si source. The n-type dopant is one of phosphorus (P), arsenic (As), or antimony (Sb).

In other embodiments, each of the plurality of source/drain regions 130 includes a SiGe layer doped with a p-type dopant. For example, to form the plurality of source/drain regions 130, a silicon (Si) source and a germanium (Ge) source may be used. One or more of silane (SiH₄), disilane (Si₂H₆), trisilane (Si₃H₈), and/or dichlorosilane (SiH₂Cl₂) can be used as the Si source. One or more of germane (GeH₄), digermane (Ge₂H₆), trigermane (Ge₃H₈), tetragermane (Ge₄H₁₀), and/or dichlorogermane (Ge₂H₂Cl₂) can be used as the Ge source. The p-type dopant is one of boron (B) or gallium (Ga).

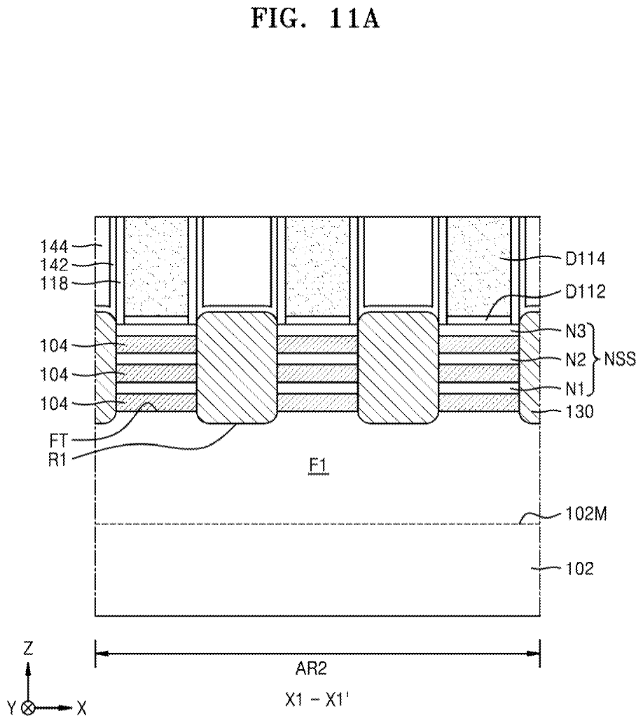

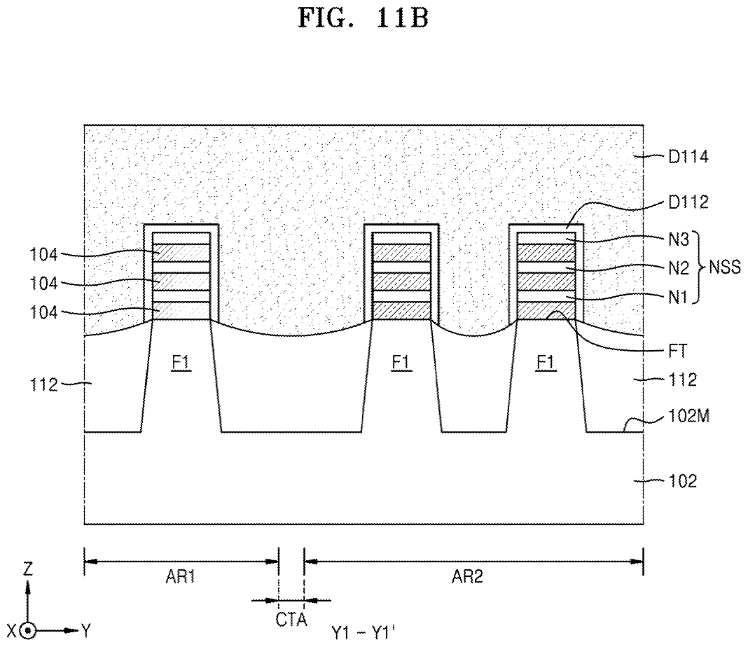

Referring to FIGS. 11A and 11B, in an embodiment, in the resultant structure of FIGS. 10A and 10B, an insulating liner 142 is formed that covers respective surfaces of the source/drain regions 130, respective surfaces of a plurality of insulating spacers 118, and an exposed surface of the device isolation film 112, and an inter-gate dielectric film 144 is formed on the insulating liner 142. Thereafter, the capping layer D116 is removed, and the plurality of insulating spacers 118, the insulating liner 142, and the inter-gate dielectric film 144 are removed from a top surface of the dummy gate layer D114 to expose the top surface of the dummy gate layer D114.

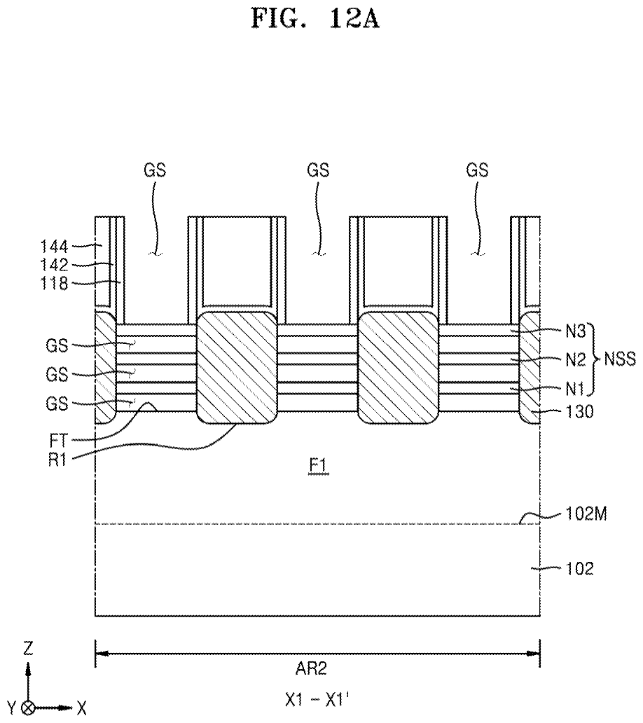

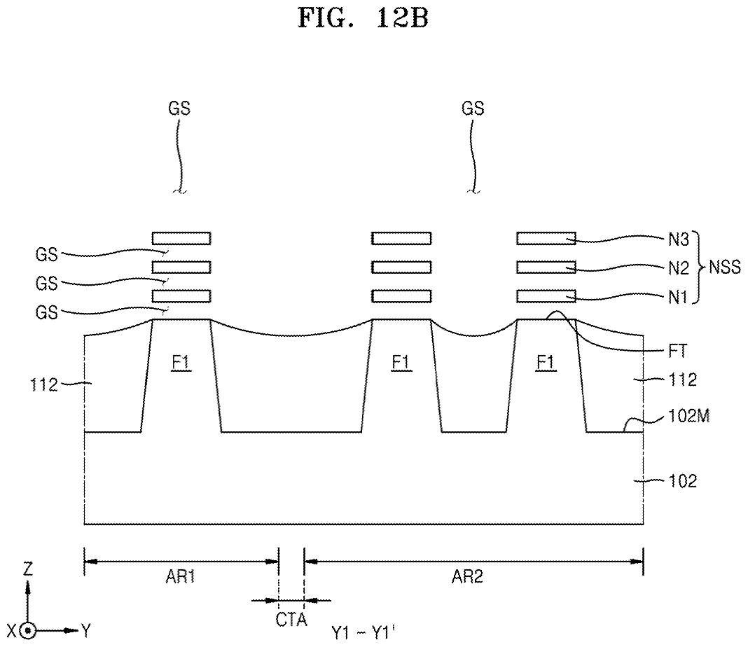

Referring to FIGS. 12A and 12B, in an embodiment, in the resultant structures of FIGS. 11A and 11B, a plurality of gate spaces GS are prepared by removing the exposed dummy gate layer D114 and the oxide film D112 disposed thereunder, and the plurality of nanosheet stacks NSS are exposed by the plurality of gate spaces GS. Afterwards, the plurality of sacrificial semiconductor layers 104 that remain on the resultant structure are removed through the gate spaces GS, and thus, each of the gate spaces GS extends to respective spaces between the first to third nanosheets N1, N2, and N3 and a space between the first nanosheet N1 and the fin top surface FT.

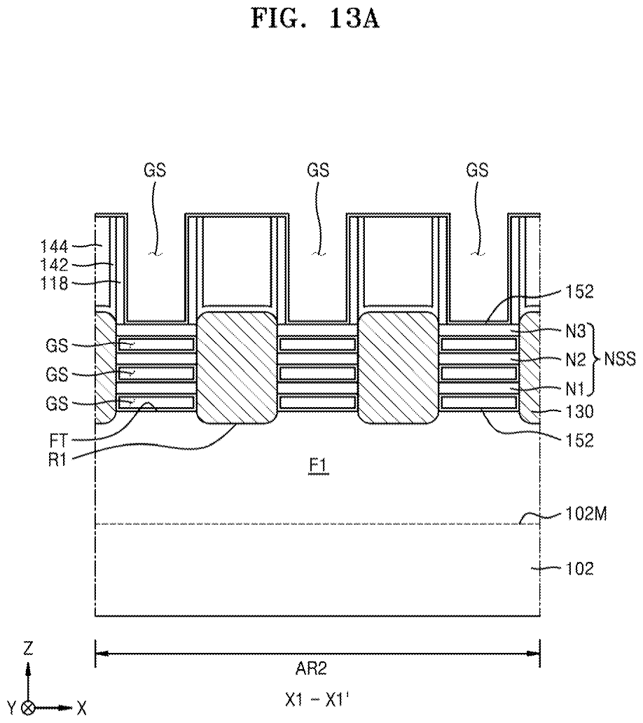

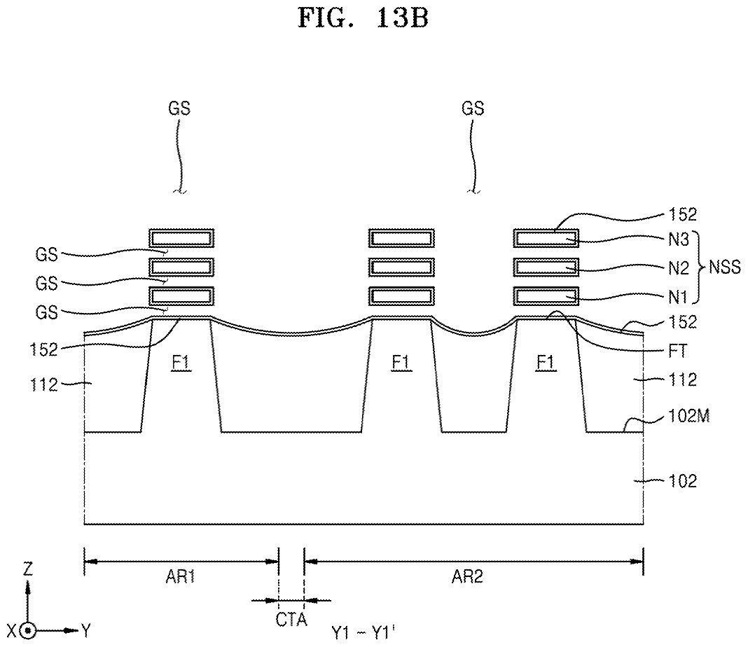

Referring to FIGS. 13A and 13B, in an embodiment, a gate dielectric film 152 is formed that conformally covers exposed surfaces in the resultant structure of FIGS. 12A and 12B.

The gate dielectric film 152 includes a portion that covers exposed surfaces of each of the first to third nanosheets N1, N2, and N3, a portion that covers exposed surfaces of each of the plurality of fin-type active regions F1, a portion that covers exposed surfaces of each of the plurality of insulating spacers 118, and portions that cover exposed surfaces of the device isolation film 112. The gate dielectric film 152 can be formed by using an ALD process.

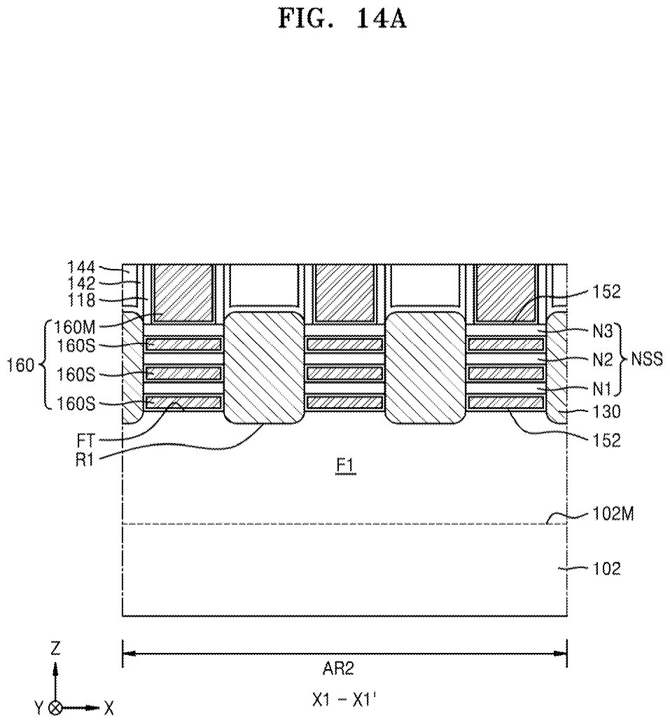

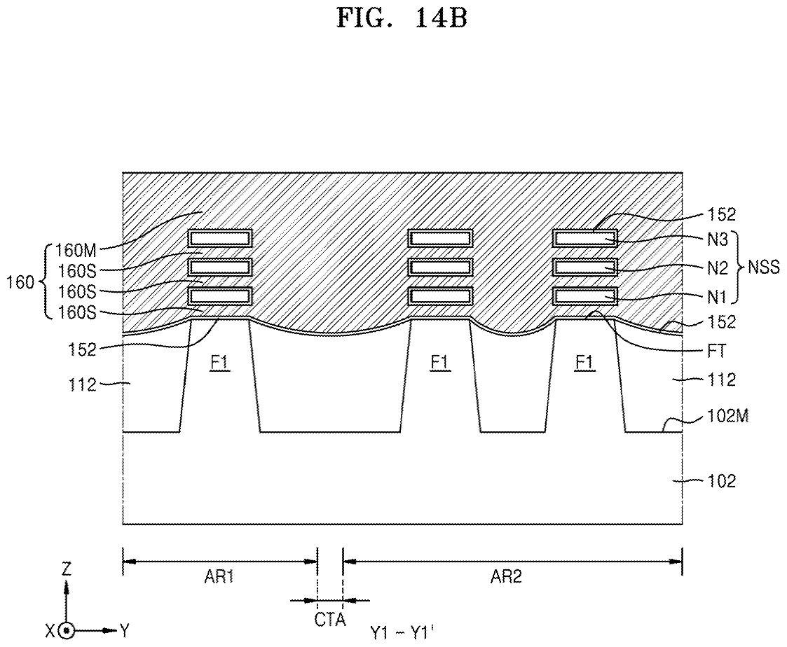

Referring to FIGS. 14A and 14B, in an embodiment, a plurality of gate lines 160 that fill the plurality of gate spaces (refer to GS in FIGS. 13A and 13B) are formed on the gate dielectric film 152. The resultant structure is planarized such that respective top surfaces of the gate line 160, the gate dielectric film 152, the insulating liner 142, and the inter-gate dielectric film 144 are coplanar with each other.

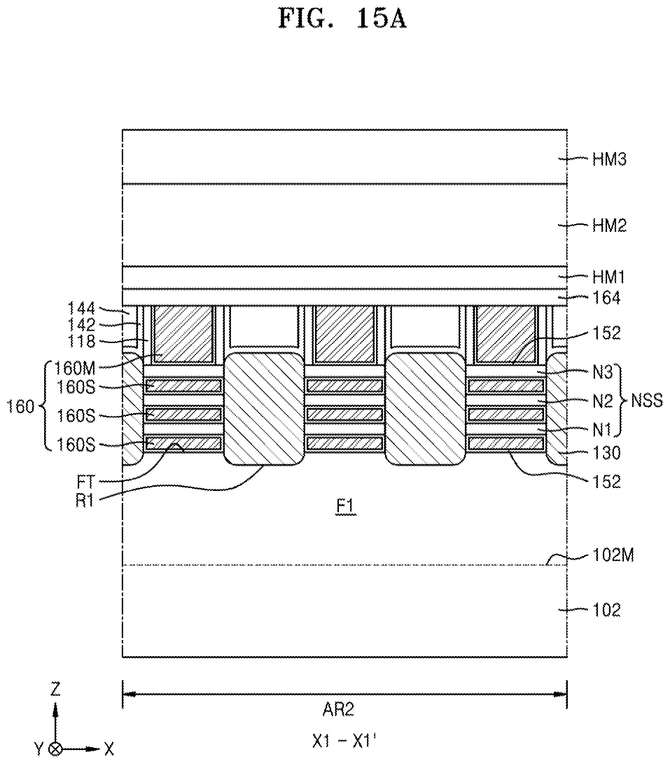

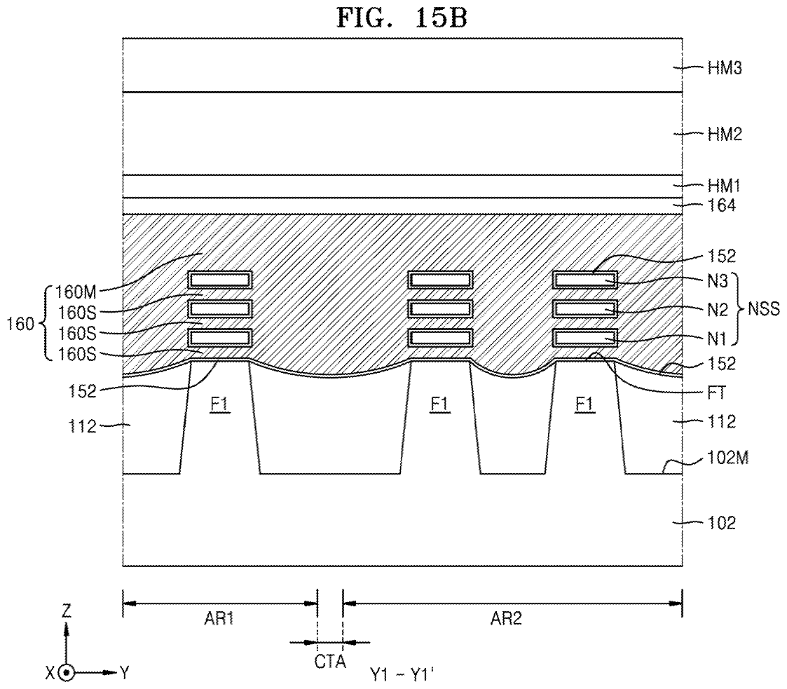

Referring to FIGS. 15A and 15B, in an embodiment, a capping insulating layer 164 is formed on the resultant structure of FIGS. 14A and 14B. The capping insulating layer 164 is formed to extend in a lateral direction (e.g., X direction and Y direction) and covers the top surface of each of the gate line 160, the gate dielectric film 152, the insulating liner 142, and the inter-gate dielectric film 144. In embodiments, the capping insulating layer 164 is formed to a thickness of about 5 nm to about 10 nm, such as a thickness of 7 nm.

A first hard mask layer HM1, a second hard mask layer HM2, and a third hard mask layer HM3 are sequentially formed on the capping insulating layer 164. The first hard mask layer HM1 includes a silicon oxide film that has a thickness of about 10 nm to about 20 nm. The second hard mask layer HM2 includes a silicon nitride film that has a thickness of about 100 nm to about 150 nm. The third hard mask layer HM3 includes a silicon oxide film and has a thickness of about 20 nm to about 50 nm. However, respective thicknesses and constituent materials of the first hard mask layer HM1, the second hard mask layer HM2, and the third hard mask layer HM3 are not necessarily limited to the examples described above.

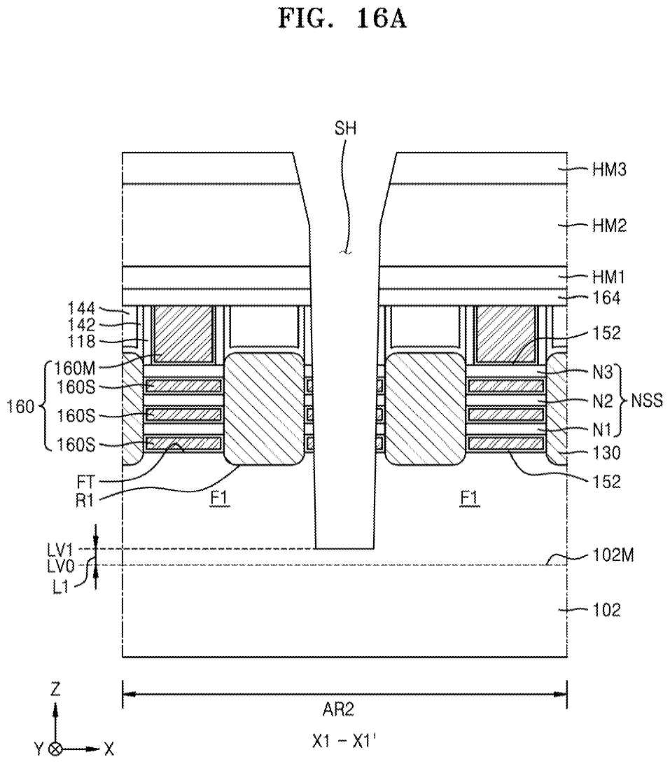

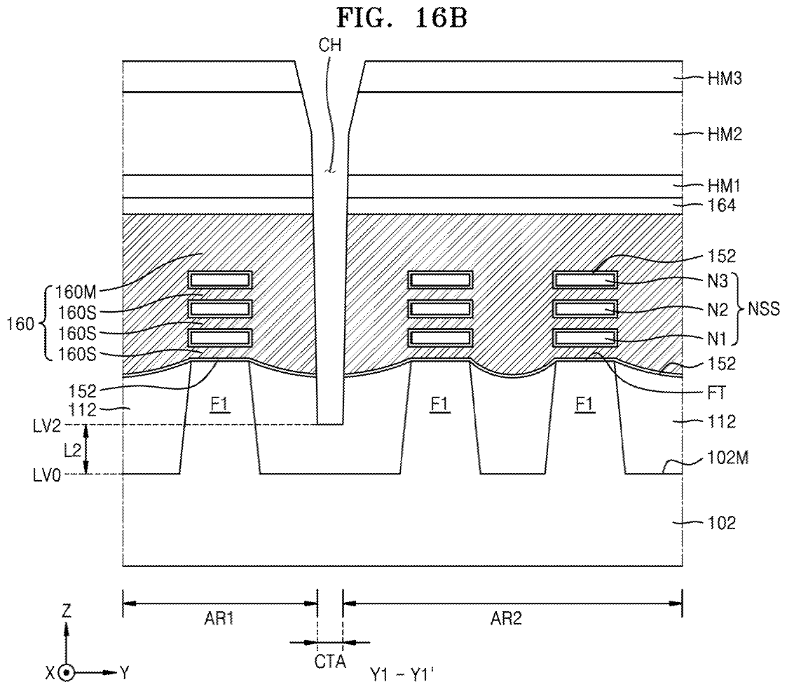

Referring to FIGS. 16A and 16B, in an embodiment, portions of the resultant structure of FIGS. 15A and 15B are etched, and thus, a fin isolation hole SH and a gate cut hole CH are formed. The fin isolation hole SH and the gate cut hole CH are simultaneously formed. To form the fin isolation hole SH and the gate cut hole CH, an anisotropic dry etching process is performed by using the third hard mask layer HM3 as an etch mask in the vertical direction (Z direction). An etch rate is increased in the lateral direction (e.g., the X direction and the Y direction) such that, in the lateral direction, a width of an entrance side of each of the fin isolation hole SH and the gate cut hole CH is greater than widths of other portions thereof. During the formation of the fin isolation hole SH and the gate cut hole CH, a portion of the third hard mask layer HM3 is consumed. As a result, after the fin isolation hole SH and the gate cut hole CH are formed, a thickness of the third hard mask layer HM3 in the vertical direction (Z direction) is reduced.

The fin isolation hole SH is formed at a position that corresponds to a fin isolation insulating portion (refer to 190 in FIGS. 1 and 2A), and the gate cut hole CH is formed at a position that corresponds to a gate cut insulating portion 150. A width of the fin isolation hole SH in the first lateral direction (X direction) is greater than a width of the gate cut hole CH in the second lateral direction (Y direction). In the vertical direction (Z direction), a length of the fin isolation hole SH is greater than a length of the gate cut hole CH.

As shown in FIG. 16A, a bottom surface of the fin isolation hole SH is spaced apart from a main surface 102M of the substrate 102 in the vertical direction (Z direction). A first vertical distance L1 between a vertical level LV0 of the main surface 102M of the substrate 102 and a vertical level LV1 of the bottom surface of the fin isolation hole SH is greater than 0. As shown in FIG. 16B, a bottom surface of the gate cut hole CH us spaced apart in the vertical direction (Z direction) from the main surface 102M of the substrate 102 with the device isolation film 112 therebetween. A second vertical distance L2 between the vertical level LV0 of the main surface 102M of the substrate 102 and a vertical level LV2 of the bottom surface of the gate cut hole CH is greater than 0. The first vertical distance L1 is less than the second vertical distance L2.

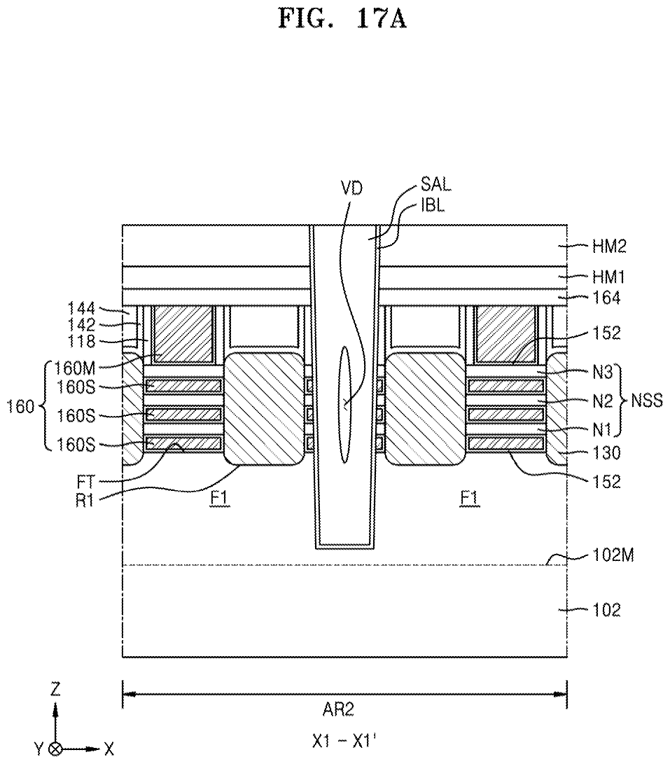

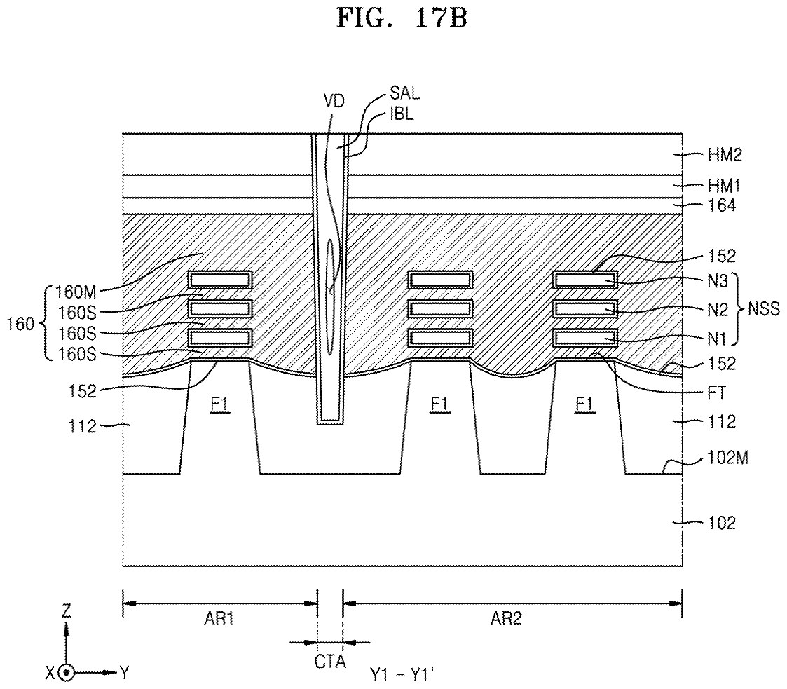

Referring to FIGS. 17A and 17B, in an embodiment, in the resultant structure of FIGS. 16A and 16B, an insulating liner IBL is formed that covers an inner surface of each of the fin isolation hole SH and the gate cut hole CH. A sacrificial film SAL is formed on the insulating liner IBL that fills an inner space of each of the fin isolation hole SH and the gate cut hole CH. The resultant structure is planarized to expose the second hard mask layer HM2. In this process, portions of the third hard mask layer HM3 and the second hard mask layer HM2 are consumed. In the resultant structure, a thickness of the remaining second hard mask layer HM2 in the vertical direction (Z direction) is reduced.

The insulating liner IBL includes the same materials as a constituent material of each of the isolation insulating liner IB1 and the cut insulating liner IB2 that have been described with reference to FIGS. 2A to 2D. In embodiments, the sacrificial film SAL includes a silicon oxide film, without necessarily being limited thereto.

In the process of forming the sacrificial film SAL to fill the inner space of each of the fin isolation hole SH and the gate cut hole CH, because each of the first to third hard mask layers HM1, HM2, and HM3 remaining on the resultant structure of FIGS. 16A and 16B has a relatively great thickness, aspect ratios of spaces to be filled by the sacrificial film SAL are relatively high. As a result, even when the width of the entrance side of each of the fin isolation hole SH and the gate cut hole CH is greater than the widths of the other portions in the lateral direction, as shown in FIGS. 17A and 17B, a plurality of voids VD are formed in the sacrificial film SAL.

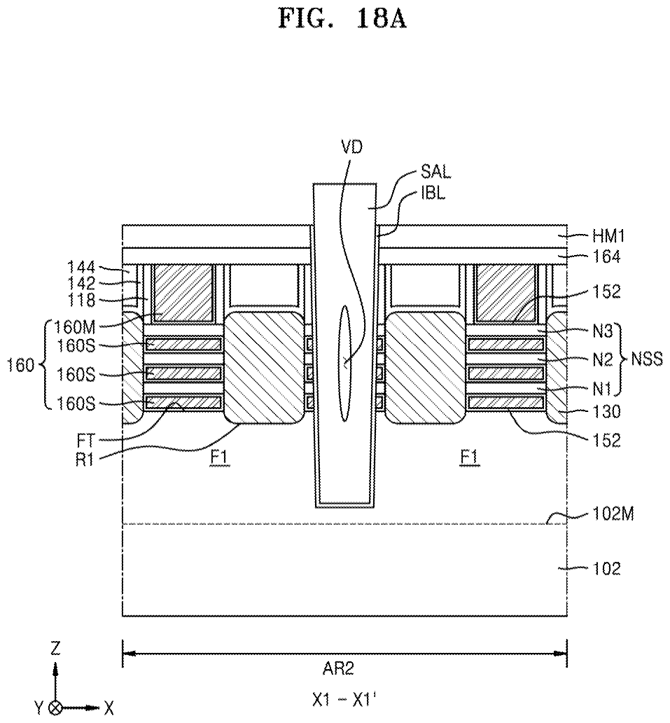

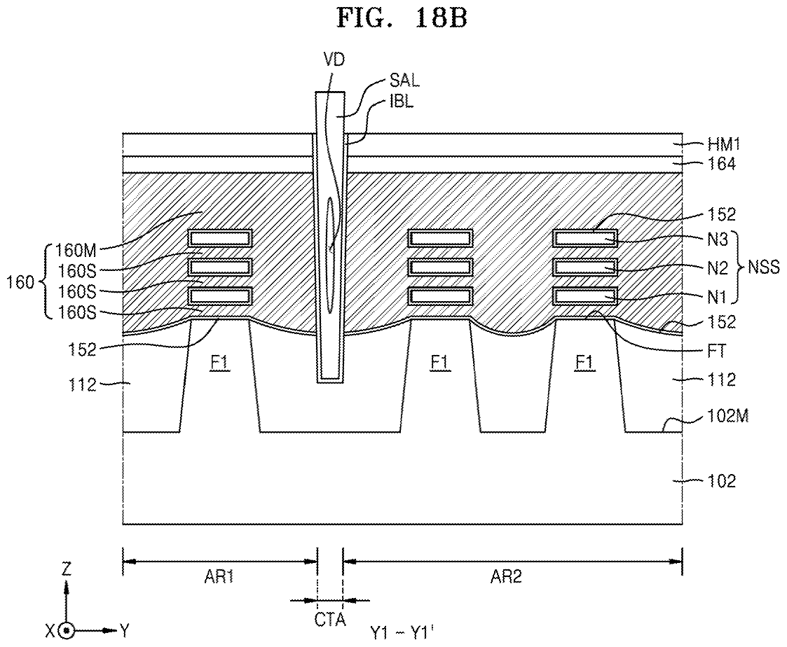

Referring to FIGS. 18A and 18B, in an embodiment, in the resultant structure of FIGS. 17A and 17B, the second hard mask layer HM2 and a portion of the insulating liner IBL that is in contact with the second hard mask layer HM2 are removed by using an etchback process. As a result, an upper portion of the sacrificial film SAL protrudes over a top surface of the first hard mask layer HM1.

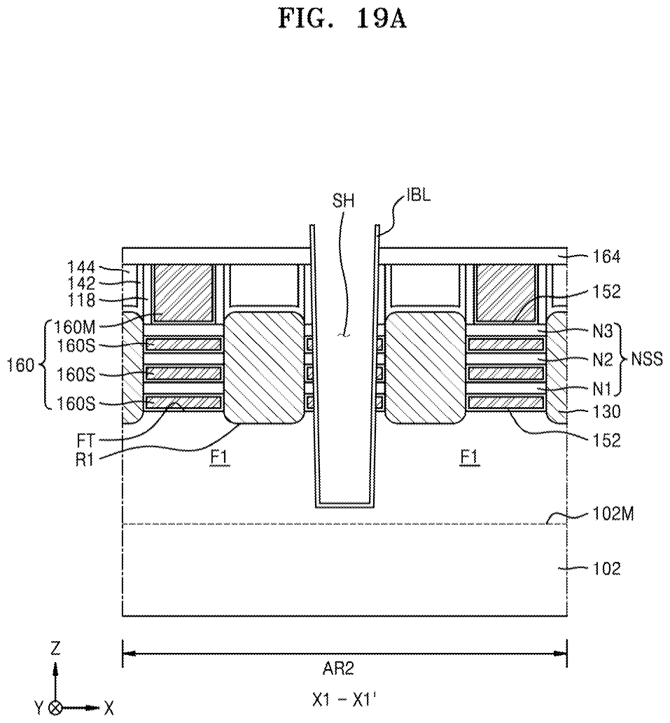

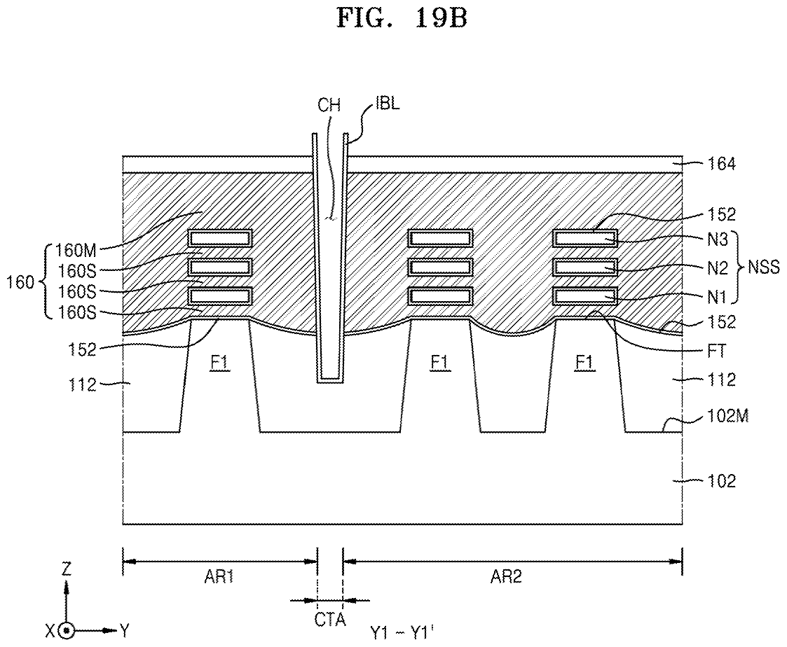

Referring to FIGS. 19A and 19B, in an embodiment, the first hard mask layer HM1 and the sacrificial film SAL are removed from the resultant structure of FIGS. 18A and 18B. Thus, the top surface of the capping insulating layer 164 is exposed, and the insulating liner IBL is exposed inside each of the fin isolation hole SH and the gate cut hole CH. An upper portion of the insulating liner IBL remains protruding over the top surface of the capping insulating layer 164. In embodiments, the first hard mask layer HM1 and the sacrificial film SAL are removed by using a wet etching process.

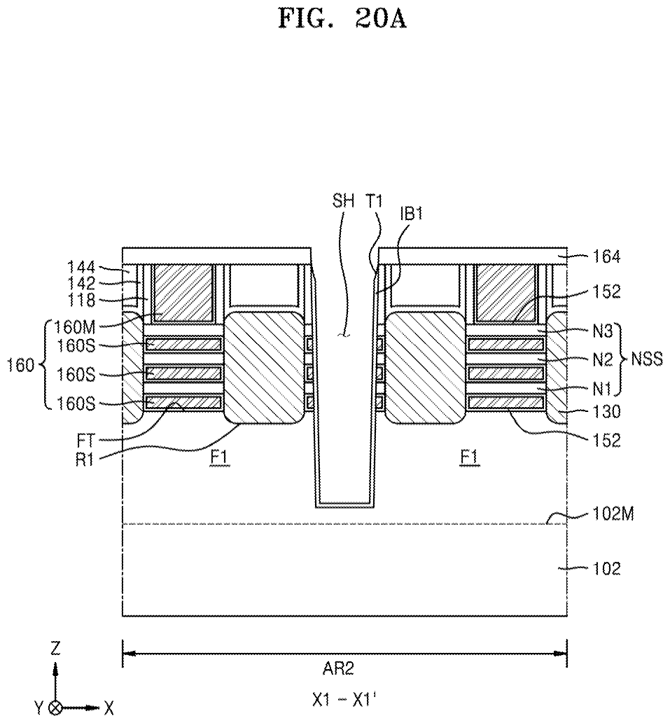

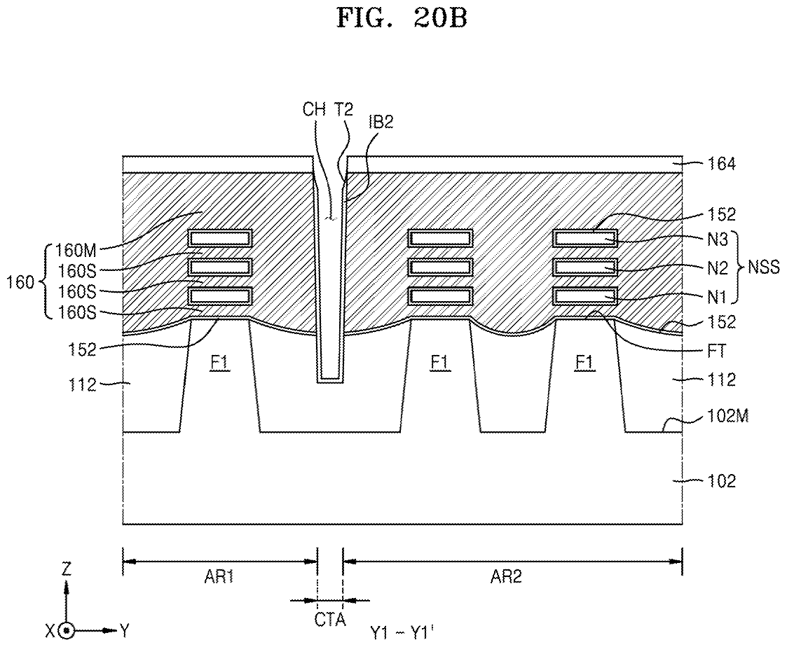

Referring to FIGS. 20A and 20B, in an embodiment, a chamfering process is performed that removes the upper portion of the insulating liner IBL from the resultant structure of FIGS. 19A and 19B. In embodiments, the chamfering process is performed by using a wet etching process. After the chamfering process is performed on the insulating liner IBL, a portion of the insulating liner IBL that remains inside the fin isolation hole SH constitutes the isolation insulating liner IB1, and a portion of the insulating liner IBL that remains inside the gate cut hole CH constitutes the cut insulating liner IB2. The isolation insulating liner IB1 includes a chamfer top surface T1 in a region adjacent to an entrance of the fin isolation hole SH that is located at a lower vertical level than the capping insulating layer 164. The cut insulating liner 1B2 includes a chamfer top surface T2 in a region adjacent to an entrance of the gate cut hole CH that is located at a lower vertical level than the capping insulating layer 164.

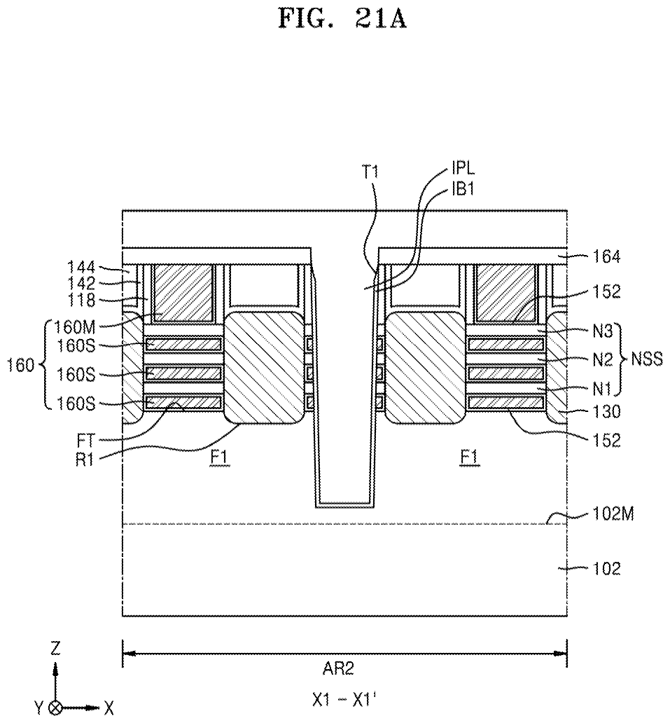

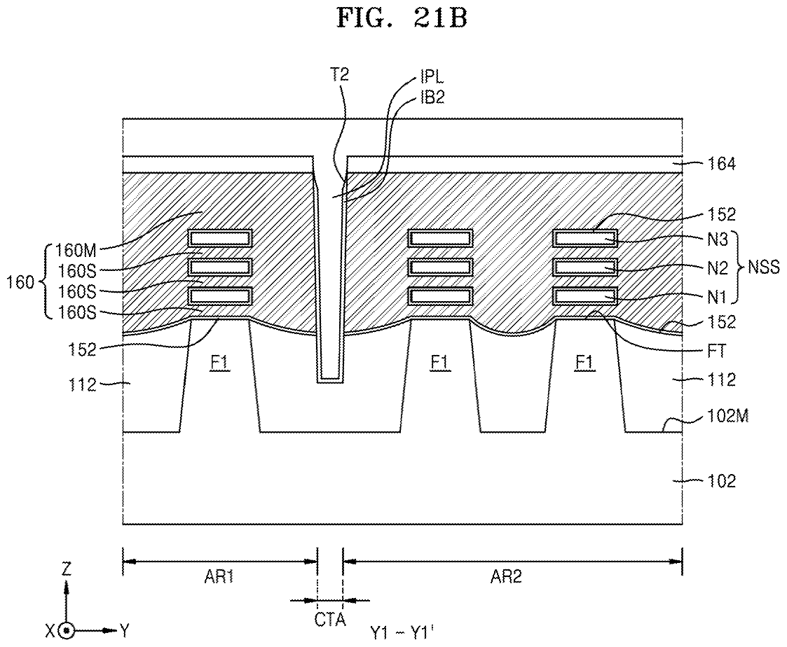

Referring to FIGS. 21A and 21B, in an embodiment, an insulating layer IPL is formed on the resultant structure of FIGS. 20A and 20B. The insulating layer IPL is formed to a thickness sufficient to fill the fin isolation hole SH on the isolation insulating liner IB1 and the gate cut hole CH on the cut insulating liner IB2.

Because the isolation insulating liner IB1 includes the chamfer top surface T1 in the region adjacent to the entrance of the fin isolation hole SH and the cut insulating liner IB2 includes the chamfer top surface T2 in the region adjacent to the entrance of the gate cut hole CH, materials required for forming the insulating layer IPL can be smoothly supplied into each of the fin isolation hole SH and the gate cut hole CH during the formation of the insulating layer IPL. In addition, no other layer, such as a hard mask layer, is disposed on the capping insulating layer 164, and an aspect ratio of each of the fin isolation hole SH and the gate cut hole CH to be filled by the insulating layer IPL is relatively low. Accordingly, no voids are formed in the insulating layer IPL inside each of the fin isolation hole SH and the gate cut hole CH.

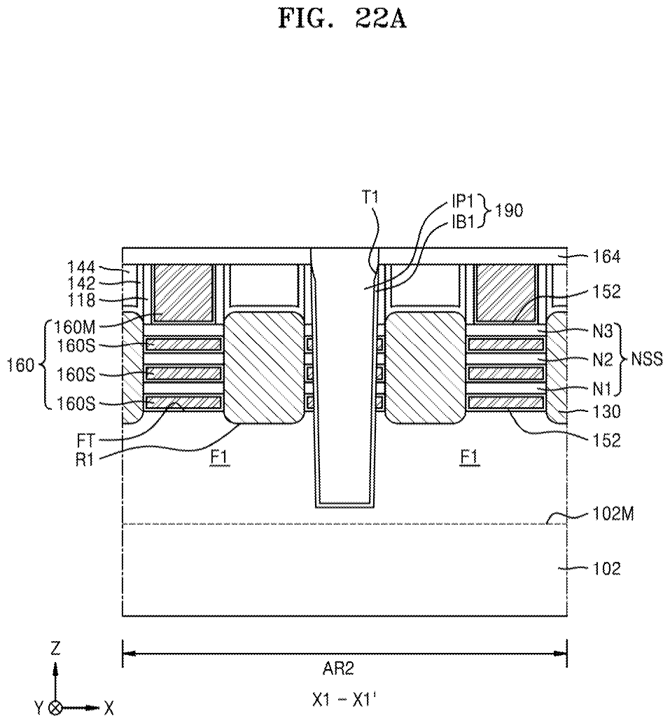

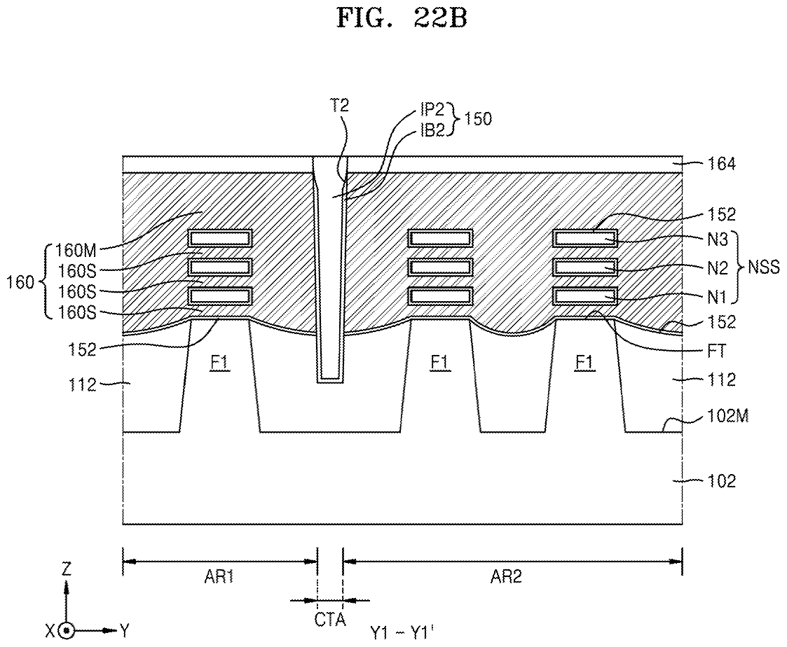

Referring to FIGS. 22A and 22B, in an embodiment, unnecessary portions that remain on the capping insulating layer 164 are removed from the resultant structure of FIGS. 21A and 21B and expose the top surface of the capping insulating layer 164. Thus, the resultant structure is obtained that has a planarized top surface. In the resultant structure, a portion of the insulating layer IPL that remains inside the fin isolation hole SH constitutes an isolation insulating plug IP1, and a portion of the insulating layer IPL that remains inside the gate cut hole CH constitutes a cut insulating plug IP2.

Although a method of manufacturing the semiconductor device 100 shown in FIGS. 1 and 2A to 2D has been described with reference to FIGS. 6A to 22B, it will be understood that the IC devices 200, 300, and 400 shown in FIGS. 3A, 3B, 4, and 5 or IC devices having variously changed structures can be manufactured by applying various modifications and changes to processes described with reference to FIGS. 6A to 22B within the scope of embodiments of the inventive concept.

For example, to manufacture the IC device 200 shown in FIGS. 3A and 3B, a portion of each of the capping insulating layer 164, the inter-gate dielectric film 144, and the insulating liner 142 is removed from the resultant structure of FIGS. 22A and 22B, and thus, a plurality of contact holes 270H that expose partial regions of the source/drain region 130 are formed. Thereafter, a metal silicide film 272 is formed on respective surfaces of the plurality of source/drain regions 130 that are exposed through the plurality of contact holes 270H, and a plurality of source/drain contacts 274 are formed that fill the plurality of contact holes 270H, respectively. Thus, the IC device 200 shown in FIGS. 3A and 3B can be manufactured.

To manufacture the IC devices 300 and 400 shown in FIGS. 4 and 5, when a chamfering process is performed in the process described with reference to FIGS. 20A and 20B that removes the upper portion of the insulating liner IBL, not only the insulating liner IBL but also respective portions of the insulating spacers 118, the capping insulating layer 164, and the gate line 160 that are adjacent to the insulating liner IBL are removed together, and thus, a width of an entrance side of each of the fin isolation hole SH and the gate cut hole CH is further increased. Afterwards, the processes described with reference to FIGS. 21A to 22B are performed, and thus, the IC devices 300 and 400 shown in FIGS. 4 and 5 are manufactured.

While embodiments of the inventive concept have been particularly shown and described with reference to drawings thereof, it will be understood that various changes in form and details may be made therein without departing from the spirit and scope of the following claims.

What is claimed is:

1. An integrated circuit device, comprising:
a pair of fin-type active regions that extend in a first lateral direction on a substrate, wherein the pair of fin-type active regions are collinear with each other in the first lateral direction;
a first gate line that extends in a second lateral direction on one of the fin-type active regions, wherein the second lateral direction crosses the first lateral direction;
a capping insulating layer that covers a top surface of the first gate line; and
a fin isolation insulating portion that extends in the second lateral direction between the pair of fin-type active regions, wherein the fin isolation insulating portion passes through the capping insulating layer in a vertical direction that is perpendicular to a plane defined by the first lateral direction and the second lateral direction,
wherein the fin isolation insulating portion comprises:
an isolation insulating plug that includes a first portion and a second portion, wherein the first portion is interposed between the pair of fin-type active regions, and the second portion is integrally connected to the first portion and passes through the capping insulating layer in the vertical direction; and
an isolation insulating liner that surrounds a bottom surface and a sidewall of the isolation insulating plug, wherein the isolation insulating liner includes an uppermost portion that is closer to the substrate than a top surface of the isolation insulating plug.

2. The integrated circuit device of claim 1, wherein the isolation insulating liner comprises a chamfer top surface that extends into the fin isolation insulating portion in the first lateral direction as the chamfer top surface extends from the uppermost portion of the isolation insulating liner toward the substrate, and
the isolation insulating plug comprises a portion in contact with the chamfer top surface, wherein the portion overlaps the isolation insulating liner in the vertical direction and the first lateral direction.

3. The integrated circuit device of claim 1, wherein the isolation insulating top surface of the isolation insulating plug is coplanar with a top surface of the capping insulating layer, and a sidewall of the second portion of the isolation insulating plug is in contact with the capping insulating layer, and
the uppermost portion of the isolation insulating liner is closer to the substrate than the top surface of the capping insulating layer.

4. The integrated circuit device of claim 1, wherein each of the isolation insulating liner and the capping insulating layer comprises one of a silicon nitride film or a silicon carbonitride (SiCN) film, and
the isolation insulating plug comprises at least one of a silicon oxide film, a silicon oxynitride (SiON) film, a silicon oxycarbonitride (SiOCN) film, a SiCN film, a silicon nitride film, or a combination thereof.

5. The integrated circuit device of claim 1, wherein the isolation insulating liner comprises a chamfer top surface that extends into the fin isolation insulating portion in the first lateral direction as the chamfer top surface extends from the uppermost portion of the isolation insulating liner toward the substrate, and
the sidewall of the isolation insulating plug comprises a lower sidewall and an upper sidewall, wherein the lower sidewall is closer to the substrate than an end portion of the chamfer top surface that is closest to the substrate, and the upper sidewall is farther from the substrate than the chamfer end portion, and
a slope of the lower sidewall differs from a slope of the upper sidewall.

6. The integrated circuit device of claim 1, wherein the isolation insulating plug comprises a portion that protrudes in the first lateral direction further outward from the fin isolation insulating portion than the isolation insulating liner.

7. The integrated circuit device of claim 1, further comprising:
at least one nanosheet disposed on the one selected fin-type active region, wherein the at least one nanosheet is surrounded by the first gate line;
a source/drain region disposed on the one selected fin-type active region between the first gate line and the fin isolation insulating portion; and
an inter-gate dielectric film that covers the source/drain region, wherein the inter-gate dielectric film is interposed between the first gate line and the fin isolation insulating portion in the first lateral direction,
wherein the capping insulating layer covers a top surface of the inter-gate dielectric film.

8. The integrated circuit device of claim 1, further comprising:
a second gate line that is spaced apart from the first gate line in the second lateral direction, wherein the second gate line extends along an extension line of the first gate line in the second lateral direction; and
a gate cut insulating portion disposed between the first gate line and the second gate line, wherein the gate cut insulating portion extends in the first lateral direction,
wherein the gate cut insulating portion is integrally connected to the fin isolation insulating portion.

9. The integrated circuit device of claim 8, wherein the gate cut insulating portion comprises:
a cut insulating plug that comprises a third portion and a fourth portion, wherein the third portion is disposed between the first gate line and the second gate line, and the fourth portion is integrally connected to the third portion and passes through the capping insulating layer in the vertical direction; and
a cut insulating liner that surrounds a bottom surface and a sidewall of the cut insulating plug, wherein the cut insulating liner includes an uppermost portion that is closer to the substrate than a top surface of the cut insulating plug,
wherein the cut insulating plug and the isolation insulating plug are integrally connected to each other and comprise the same materials as each other, and
the cut insulating liner and the isolation insulating liner are integrally connected to each other and comprise the same materials as each other.

10. The integrated circuit device of claim 8, wherein the gate cut insulating portion comprises:
a cut insulating plug that includes a third portion and a fourth portion, wherein the third portion is disposed between the first gate line and the second gate line, and the fourth portion is integrally connected to the third portion and passes through the capping insulating layer in the vertical direction; and
a cut insulating liner that surrounds a bottom surface and a sidewall of the cut insulating plug, wherein the cut insulating liner includes an uppermost portion that is closer to the substrate than a top surface of the cut insulating plug,
wherein the cut insulating liner comprises a chamfer top surface that that extends into the gate cut isolation insulating portion in the second lateral direction as the chamfer top surface extends from the uppermost portion of the cut insulating liner toward the substrate, and
the cut insulating plug comprises a portion in contact with the chamfer top surface, wherein the portion overlaps the cut insulating liner in the vertical direction and the second lateral direction.

11. The integrated circuit device of claim 8, wherein the gate cut insulating portion comprises:
a cut insulating plug that includes a third portion and a fourth portion, wherein the third portion is disposed between the first gate line and the second gate line, and the fourth portion is integrally connected to the third portion and passes through the capping insulating layer in the vertical direction; and
a cut insulating liner that surrounds a bottom surface and a sidewall of the cut insulating plug, wherein the cut insulating liner includes an uppermost portion that is closer to the substrate than a top surface of the cut insulating plug,
wherein the top surface of the cut insulating plug is coplanar with a top surface of the capping insulating layer, and a sidewall of the fourth portion of the cut insulating plug is in contact with the capping insulating layer, and
the uppermost portion of the cut insulating liner is closer to the substrate than a top surface of the capping insulating layer.

12. The integrated circuit device of claim 8, wherein the gate cut insulating portion comprises:
a cut insulating plug that includes a third portion and a fourth portion, wherein the third portion is disposed between the first gate line and the second gate line, and the fourth portion is integrally connected to the third portion and passes through the capping insulating layer in the vertical direction; and
a cut insulating liner that surrounds a bottom surface and a sidewall of the cut insulating plug, wherein the cut insulating liner includes an uppermost portion that is closer to the substrate than a top surface of the cut insulating plug,
wherein the cut insulating liner comprises a chamfer top surface that extends into the gate cut isolation insulating portion in the second lateral direction as the chamfer top surface extends from the uppermost portion of the cut insulating liner toward the substrate,
a sidewall of the cut insulating plug comprises a lower sidewall and an upper sidewall, wherein the lower sidewall is closer to the substrate than an end portion of the chamfer top surface that is closest to the substrate, and the upper sidewall is farther from the substrate than the end portion, and
a slope of the lower sidewall differs from a slope of the upper sidewall.

13. The integrated circuit device of claim 8, wherein each of the first gate line and the second gate line comprises:
a lower sidewall in contact with the cut insulating liner; and
an upper chamfer surface in contact with the cut insulating plug,
wherein, in the second lateral direction, a distance between the upper chamfer surface of the first gate line and the upper chamfer surface of the second gate line is greater than a distance between a lower sidewall of the first gate line and a lower sidewall of the second gate line.

14. The integrated circuit device of claim 8, wherein the cut insulating plug comprises a portion that protrudes in the second lateral direction further outward from the gate cut insulating portion than the cut insulating liner.

15. An integrated circuit device, comprising:
a pair of fin-type active regions that extend in a first lateral direction on a substrate, wherein the pair of fin-type active regions are collinear with each other in the first lateral direction;
a fin isolation insulating portion that extends in a second lateral direction between the pair of fin-type active regions, wherein the second lateral direction crosses the first lateral direction;
a pair of nanosheet stacks respectively disposed on the pair of fin-type active regions, wherein each nanosheet stack includes at least one nanosheet;
a first pair of gate lines that surround the at least one nanosheet on the pair of fin-type active regions, wherein the first pair of gate lines extend in the second lateral direction;
a capping insulating layer that covers top surfaces of the first pair of gate lines; and
a pair of source/drain regions respectively disposed on both sides of the fin isolation insulating portion between the first pair of gate lines,
wherein the fin isolation insulating portion comprises:
an isolation insulating plug that includes a first portion and a second portion, wherein the first portion is disposed between the pair of fin-type active regions, and the second portion is integrally connected to the first portion and passes through the capping insulating layer in a vertical direction that is perpendicular to a plane defined by the first lateral direction and the second lateral direction; and
an isolation insulating liner that surrounds a bottom surface and a sidewall of the isolation insulating plug, wherein the isolation insulating liner includes an uppermost portion that is closer to the substrate than a top surface of the isolation insulating plug.

16. The integrated circuit device of claim 15, wherein the isolation insulating liner comprises a chamfer top surface that extends into the fin isolation insulating portion in the first lateral direction as the chamfer top surface extends from the uppermost portion of the isolation insulating liner toward the substrate, and
the isolation insulating plug comprises a portion in contact with the chamfer top surface, wherein the portion overlaps the isolation insulating liner in the vertical direction and the first lateral direction.

17. The integrated circuit device of claim 15, wherein the top surface of the isolation insulating plug is coplanar with a top surface of the capping insulating layer, and a sidewall of the second portion of the isolation insulating plug is in contact with the capping insulating layer, and the uppermost portion of the isolation insulating liner is closer to the substrate than the top surface of the capping insulating layer.

18. The integrated circuit device of claim 15, wherein the isolation insulating plug comprises a portion that protrudes in the first lateral direction further outward from the fin isolation insulating portion than the isolation insulating liner.

19. The integrated circuit device of claim 15, further comprising:
a second pair of gate lines that are spaced apart from the first pair of gate lines in the second lateral direction, wherein the second pair of gate lines extend along extension lines of the first pair of gate lines in the second lateral direction; and
a gate cut insulating portion disposed between the first pair of gate lines and the second pair of gate lines, wherein the gate cut insulating portion extends in the first lateral direction,
wherein the gate cut insulating portion comprises:
a cut insulating plug that includes a third portion and a fourth portion, wherein the third portion is interposed between the first pair of gate lines and the second pair of gate lines, and the fourth portion is integrally connected to the third portion and passes through the capping insulating layer in the vertical direction; and
a cut insulating liner that surrounds a bottom surface and a sidewall of the cut insulating plug, wherein the cut insulating liner includes an uppermost portion that is closer to the substrate than a top surface of the cut insulating plug,
wherein the cut insulating plug and the isolation insulating plug are integrally connected to each other and comprise the same materials as each other, and
the cut insulating liner and the isolation insulating liner are integrally connected to each other and comprise the same materials as each other.

20. An integrated circuit device, comprising:
a pair of fin-type active regions that extend in a first lateral direction on a substrate, wherein the pair of fin-type active regions are collinear with each other in the first lateral direction;
a fin isolation insulating portion that extends in a second lateral direction between the pair of fin-type active regions, wherein the second lateral direction crosses the first lateral direction;
a pair of nanosheet stacks respectively disposed on the pair of fin-type active regions, wherein each nanosheet stack includes at least one nanosheet;
a first pair of gate lines that surround the at least one nanosheet on the pair of fin-type active regions, wherein the first pair of gate lines extend in the second lateral direction;
a second pair of gate lines that are spaced apart from the first pair of gate lines in the second lateral direction, wherein the second pair of gate lines extends along extension lines of the first pair of gate lines in the second lateral direction;
a capping insulating layer that covers respective top surfaces of the first pair of gate lines and the second pair of gate lines; and
a gate cut insulating portion disposed between the first pair of gate lines and the second pair of gate lines, wherein the gate cut insulating portion extends in the first lateral direction and is integrally connected to the fin isolation insulating portion,
wherein each of the fin isolation insulating portion and the gate cut insulating portion comprises:
an insulating plug that passes through the capping insulating layer in a vertical direction that is perpendicular to a plane defined by the first lateral direction and the second lateral direction, wherein the insulating plug includes a top surface and a sidewall in contact with the capping insulating layer, and the top surface is coplanar with a top surface of the capping insulating layer; and
an insulating liner that surrounds a bottom surface and a sidewall of the insulating plug, wherein the insulating liner includes an uppermost portion that is closer to the substrate than a top surface of the insulating plug.
